(19) United States
(12) Patent Application Publication
(10) Pub. No.: US 2026/0040566 A1
(43) Pub. Date: Feb. 5, 2026

(54) INTEGRATED CIRCUIT AND DATA STORAGE SYSTEM INCLUDING THE SAME

(71) Applicant: Samsung Electronics Co., Ltd., Suwon-si (KR)

(72) Inventors: DONGGUN KIM, Suwon-si (KR); HANMEI CHOI, Suwon-si (KR)

(21) Appl. No.: 19/046,976

(22) Filed: Feb. 6, 2025

(30) Foreign Application Priority Data
Jul. 30, 2024 (KR) 10-2024-0101141

(51) Int. Cl. H10B 43/40; H10B 41/27; H10B 41/41; H10B 43/27

(52) U.S. Cl. CPC H10B 43/40; H10B 41/27; H10B 41/41; H10B 43/27

(57) ABSTRACT

An integrated circuit device includes first conductivity-type circuit devices on the substrate, and second conductivity-type circuit devices on the substrate, where each of the first conductivity-type circuit devices includes a first gate structure including a first interfacial insulating layer on the substrate, a first gate dielectric layer on the first interfacial insulating layer, a first work function tuning layer on the first gate dielectric layer, and first gate conductive layers on the first work function tuning layer, where each of the second conductivity-type circuit devices includes a second gate structure including a second interfacial insulating layer on the substrate, a second gate dielectric layer on the second interfacial insulating layer, a diffusion barrier on the second gate dielectric layer, a second work function tuning layer on the diffusion barrier, and second gate conductive layers on the second work function tuning layer.

### CROSS-REFERENCE TO RELATED APPLICATION

This application is based on and claims priority under 35 U.S.C. § 119 to Korean Patent Application No. 10-2024-0101141, filed on Jul. 30, 2024, in the Korean Intellectual Property Office, the disclosure of which is incorporated herein by reference in its entirety.

### TECHNICAL FIELD

The inventive concept relates to an integrated circuit device and a data storage system including the same.

### BACKGROUND

An integrated circuit device able to store high-capacity data in a data storage system requiring data storage has been required. Accordingly, a method for increasing data storage capacity of an integrated circuit device has been researched. As a method for increasing data storage capacity of an integrated circuit device, an integrated circuit device including memory cells disposed three-dimensionally, instead of memory cells disposed two-dimensionally, has been suggested. Circuit devices driving memory cells may include complementary metal-oxide-semiconductor (CMOS) transistors.

### SUMMARY

According to an aspect of the inventive concept, there is provided an integrated circuit device which may include a stack structure such that each of transistors in a CMOS transistor has a corresponding work function and may reduce a height difference.

The inventive concept provides a data storage system including an integrated circuit device which may include a stack structure such that each of transistors in a CMOS transistor has a corresponding work function and may reduce a height difference.

According to an aspect of the inventive concept, there is provided an integrated circuit device a substrate; a first conductivity-type circuit device extending at least partially within the substrate; and comprising: a first gate structure including a first interfacial insulating layer on the substrate; a first gate dielectric layer on the first interfacial insulating layer; a first work function tuning layer on the first gate dielectric layer; and at least one first gate conductive layer on the first work function tuning layer; and a first source/drain region of first conductivity type extending within the substrate and on opposite sides of the first gate structure, and a second conductivity-type circuit device extending at least partially within the substrate and comprising: a second gate structure including a second interfacial insulating layer on the substrate; a second gate dielectric layer on the second interfacial insulating layer; a diffusion barrier layer on the second gate dielectric layer; a second work function tuning layer on the diffusion barrier layer; and at least one second gate conductive layer on the second work function tuning layer; and second source/drain regions of second conductivity type, extending within the substrate and on opposite sides of the second gate structure.

According to an aspect of the inventive concept, there is provided an integrated circuit device including a memory cell structure including a plurality of gate electrodes, a plurality of channel structures extending through the plurality of gate electrodes, and a plurality of contact plugs electrically connected to the plurality of gate electrodes, and a first structure electrically connected to the memory cell structure where the first structure includes a substrate, a low-voltage device region and a high-voltage device region, where the low-voltage device region comprises a plurality of first circuit devices of a plurality of first conductivity-type circuit devices and a plurality of second circuit devices of a plurality of second conductivity-type circuit devices, where the high-voltage device region includes a plurality of third circuit devices of the plurality of first conductivity-type circuit devices and a plurality of fourth circuit devices of the plurality of second conductivity-type circuit devices, where each of the plurality of first circuit devices includes a first gate structure including a first interfacial insulating layer on the substrate, a first gate dielectric layer on the first interfacial insulating layer, a first work function tuning layer on the first gate dielectric layer, and a plurality of first gate conductive layers on the first work function tuning layer, where each of the plurality of second circuit devices includes a second gate structure including a second interfacial insulating layer on the substrate, a second gate dielectric layer on the second interfacial insulating layer, a diffusion barrier on the second gate dielectric layer, a second work function tuning layer on the diffusion barrier, and a plurality of second gate conductive layers on the second work function tuning layer, where each of the plurality of third circuit devices includes a third gate structure including a third gate dielectric layer having a first thickness that is greater than a second thickness of the first gate dielectric layer and a third thickness of the second gate dielectric layer on the substrate, and a plurality of third gate conductive layers on the third gate dielectric layer, where each of the plurality of fourth circuit devices includes a fourth gate structure including the third gate dielectric layer on the substrate, and the plurality of third gate conductive layers on the third gate dielectric layer, and where the first work function tuning layer and the second work function tuning layer include a high reactivity metal, and a first concentration of the high reactivity metal in the first work function tuning layer is less than a second concentration of the high reactivity metal in the second work function tuning layer.

According to an aspect of the inventive concept, a data storage system includes an integrated circuit device including a first substrate structure including a substrate, a plurality of first conductivity-type circuit devices and a plurality of second conductivity-type circuit devices on the substrate, a second substrate structure including a plurality of gate electrodes, and an input/output pad electrically connected to the plurality of first conductivity-type circuit devices and the plurality of second conductivity-type circuit devices, and a controller electrically connected to the integrated circuit device through the input/output pad and configured to control the integrated circuit device, where each of the plurality of first conductivity-type circuit devices includes a first gate structure including a first interfacial insulating layer on the substrate, a first gate dielectric layer on the first interfacial insulating layer, a first work function tuning layer on the first gate dielectric layer, and a plurality of first gate conductive layers on the first work function tuning layer, and a first source/drain region in the substrate on opposite sides of the first gate structure, where each of the plurality of second conductivity-type circuit devices includes a second gate structure including a second interfacial insulating layer on the substrate, a second gate dielectric layer on the second interfacial insulating layer, a diffusion barrier on the second gate dielectric layer, a second work function tuning layer on the diffusion barrier, and a plurality of second gate conductive layers on the second work function tuning layer, and a second source/drain region in the substrate on opposite sides of the second gate structure.

### BRIEF DESCRIPTION OF DRAWINGS

Example embodiments of the inventive concept will be more clearly understood from the following detailed description taken in conjunction with the accompanying drawings in which:

FIG. 1 is a plan view illustrating integrated circuit device integrated circuit device according to example embodiments of the present disclosure;

FIG. 2 is a cross-sectional view illustrating the integrated circuit device illustrated in FIG. 1 according to example embodiments of the present disclosure;

FIGS. 3 to 5 cross-sectional views illustrating an integrated circuit device according to example embodiments of the present disclosure;

FIG. 6 is a cross-sectional view illustrating an integrated circuit device according to example embodiments of the present disclosure;

FIGS. 7 and 8 are enlarged views illustrating an integrated circuit device in FIG. 6 according to example embodiments of the present disclosure;

FIG. 9 is a cross-sectional view illustrating an integrated circuit device according to example embodiments of the present disclosure;

FIGS. 10A, 10B, 10C, 10D, 10E, 10F, 10G, 10H, 10I, 10J, and 10K are cross-sectional views illustrating a method of manufacturing an integrated circuit device according to example embodiments of the present disclosure;

FIG. 11 is a perspective view illustrating a data storage system including an integrated circuit device according to example embodiments of the present disclosure; and

FIG. 12 is a perspective view illustrating a data storage system including an integrated circuit device according to example embodiments of the present disclosure.

### DETAILED DESCRIPTION

Hereinafter, example embodiments of the inventive concept will be described more fully with reference to the accompanying drawings.

The term “first,” “second,” or the like used herein may modify various elements regardless of the order and/or priority thereof, and is used only for distinguishing one element from another element, without limiting example embodiments. The terms “comprises,” “comprising,” “includes” and/or “including,” when used herein, specify the presence of stated elements, but do not preclude the presence of additional elements. The term “and/or” includes any and all combinations of one or more of the associated listed items. The term “connected” as used herein, refers to electrical and/or physical connection between elements or components and does not preclude the presence of additional elements or components therebetween. The term “cover,” “covers,” or the like used herein may specify an element that is partially or fully, on, surrounding, or encasing another element. The term “in contact with” may be used herein to specify an element or layer that is directly adjacent to another element or layer without the presence of at least one additional element or layer therebetween. Likewise, when components or layers are referred to herein as “directly” on, or “in direct contact” or “directly connected” or “directly bonded,” no intervening components or layers are present. The term “overlap,” “overlaps,” and/or “overlapping,” when used herein may specify the position of an element as on, in contact with, and/or covering another element. Components or layers described with reference to “overlap” in a particular direction may be at least partially obstructed by one another when viewed along a line extending in the particular direction or in a plane perpendicular to the particular direction.

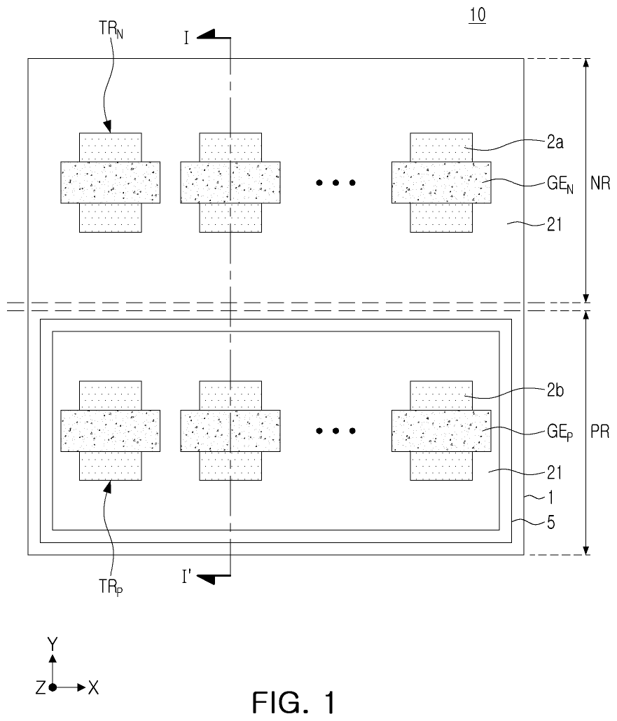

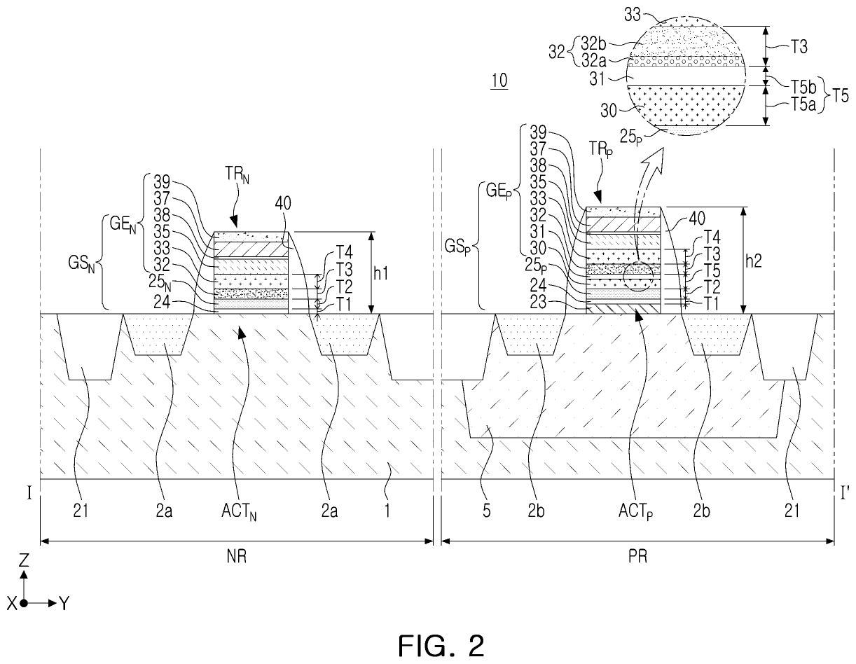

FIG. 1 is a plan view illustrating an integrated circuit device according to example embodiments. FIG. 2 is a cross-sectional view illustrating the integrated circuit device illustrated in FIG. 1 taken along line I-I′ according to example embodiments.

The integrated circuit device 10 may include an NMOS region NR and a PMOS region PR. The integrated circuit device 10 may include a substrate 1, device isolation layers 21 in the substrate 1, first circuit devices TR_{N} as NMOS transistors disposed on the substrate 1 in the NMOS region NR, and second circuit devices TR_{P} as PMOS transistors disposed on the substrate 1 in the PMOS region PR.

The substrate 1 may have an upper surface extending in the X-direction and the Y-direction. The device isolation layers 21 may be formed on the substrate 1 and may define active regions. First and second source/drain regions 2a and 2b including impurities may be disposed in a portion of the active regions. The substrate 1 may include an integrated circuit device material, for example, a group IV integrated circuit device, a group III-V compound integrated circuit device, or a group II-VI compound integrated circuit device. For example, the substrate 1 may be provided as a single crystal silicon bulk wafer.

When both NMOS region NR and PMOS region PR are disposed in the substrate 1, a well region 5 may be disposed in the substrate 1 to define the PMOS region PR when substrate 1 is a P-type substrate. The well region 5 may be doped with N-type impurities. However, example embodiments are not limited thereto, and a well region doped with P-type impurities may be further disposed in the substrate 1 to define the NMOS region NR.

The device isolation layers 21 may define active regions in the substrate 1. The device isolation layers 21 may be in the NMOS region NR and the PMOS region PR, respectively, and may be to define active regions of each transistor in the well region 5 when the NMOS region NR and/or the PMOS region PR include the well region 5. The device isolation layers 21 may be formed, for example, by a shallow trench isolation (STI) process. In example embodiments, a layout and a depth of the device isolation layers 21 may be varied. The device isolation layers 21 may be formed of an insulating material. The device isolation layer 21 may be, for example, an oxide, a nitride, or a combination thereof.

In the NMOS region NR, the first circuit devices TR_{N} may be in a matrix. The first circuit devices TR_{N} may be on an upper surface of the substrate 1 and may include planar transistors. Each first circuit device TR_{N} may include a first gate electrode structure GE_{N}, first gate dielectric structures 24 and 25_{N}, a first gate structure GS_{N} including a work function tuning layer 32, first source/drain regions 2a and first gate spacers 40.

The first gate dielectric structures 24 and 25_{N} may include a first interfacial insulating layer 24 and a first gate dielectric layer 25_{N}.

The first interfacial insulating layer 24 may be on an upper surface of the substrate 1 and may include an oxide or nitride such as silicon oxide (SiO₂), and may have a first thickness T1.

The first gate dielectric layer 25_{N} may have a second thickness T2 greater than the first thickness T1 on the first interfacial insulating layer 24, and may include a high-κ material. The high-κ material may indicate a dielectric material having a dielectric constant higher than that of silicon oxide (SiO₂). The first gate dielectric layer 25_{N} may include at least one of hafnium oxide, hafnium silicon oxide, zirconium oxide, zirconium silicon oxide, tantalum oxide, titanium oxide, barium titanium oxide, lithium oxide, aluminum oxide, or lead zinc niobate.

The first gate dielectric layer 25_{N} may include a group 3 element among transition metals, which is a high reactivity metal materials, as impurities in the high-κ material, and for example, the first gate dielectric layer 25_{N} may be doped with (or including) at least one of scandium (Sc), yttrium (Y), actinium (Ac) or lanthanum (La), and may include strontium (Sr) which is a group 2 element of period 5 or less, and/or hafnium oxide including lanthanum (La). The term “high reactivity metal” as used herein, refers to metals from group 3 transition metals, group 2 elements, hafnium, and/or a combination thereof.

The first work function tuning layer 32 may include a material having a lower areal density of oxygen atoms than that of the first gate dielectric layer 25_{N}. Due to a difference in areal density of oxygen atoms, the work function tuning layer 32 and the first gate dielectric layer 25_{N} may generate a dipole in a direction in which a work function reduces. This dipole may reduce the work function of the first gate electrode structure GE_{N}.

The first gate dielectric layer 25_{N} including the impurities may induce a dipole in the first gate dielectric layer 25_{N} when an external voltage is applied to the first gate dielectric layer 25_{N}, thereby inducing a phase change from an initial polarity state to another state. This phase change may induce a dipole such that silicon elements of the first interfacial insulating layer 24 may be arranged on an interfacial surface between the first interfacial insulating layer 24 and the first gate dielectric layer 25_{N} in a lower portion. The energy band of the first gate dielectric structures 24 and 25_{N} may be tilted by a dipole, such that the work function of the first gate electrode structure GE_{N} of the first circuit devices TR_{N}, which are NMOS transistors, may be reduced. As the work function of the NMOS transistor is reduced, the thickness of the inversion layer Tinv of the transistor may be reduced, and the threshold voltage may be reduced.

The first work function tuning layer 32 may be on the first gate dielectric layer 25_{N}. The first work function tuning layer 32 may be an oxide or oxynitride of at least one of transition metals, which are high reactivity metal materials, such as scandium (Sc), yttrium (Y), actinium (Ac), and lanthanum (La), and may be an oxide or oxynitride of strontium (Sr), which is a group 2 element of 5 periods or less. The layer may be lanthanum oxide (La₂O₃).

The first work function tuning layer 32 may be an oxide film or an oxynitride film including the same material as the impurities in the first gate dielectric layer 25_{N} in a lower portion. The impurities in the first work function tuning layer 32 may be contained in a first concentration, and the first work function tuning layer 32 may have a third thickness T3 less than or equal to the second thickness T2.

A first gate electrode structure GE_{N} may be on the first work function tuning layer 32.

The first gate electrode structure GE_{N} may include at least two layers, but example embodiments are not limited thereto. The first gate electrode structure GE_{N} may include a first conductive layer 33, a second conductive layer 35, and a third conductive layer 37 stacked in a vertical direction on the first work function tuning layer 32.

The first conductive layer 33 may include a metal or a metal nitride as a metal base layer. The first conductive layer 33 may include titanium nitride, tantalum nitride, titanium silicon nitride (TiSiN), silicon-doped titanium nitride (Si-doped TIN, TSN), or a combination thereof. The first conductive layer 33 may include titanium nitride (TiN) or TSN (Ti—Si—N), and may have a fourth thickness T4.

The second conductive layer 35 may include polysilicon, but example embodiments are not limited thereto. The third conductive layer 37 may include a metal material different from the first conductive layer 33, and may include tungsten (W), for example, but example embodiments are not limited thereto.

An ohmic contact layer 38 may be further included between the second conductive layer 35 and the third conductive layer 37, and the ohmic contact layer 38 may include titanium nitride (TiN), tantalum nitride (TaN), or the like, but example embodiments are not limited thereto. The ohmic contact layer 38 may have a thickness significantly smaller than the thicknesses of the second conductive layer 35 and the third conductive layer 37.

The first gate electrode structure GE_{N} may further include a mask layer 39 in an upper portion. The mask layer 39 may include silicon nitride, silicon oxynitride, or the like.

The first height h1 may be formed from an upper surface of the first gate structure GS_{N} to an upper surface of the substrate 1. The first height h1 may be defined as a sum of the thicknesses from a lower surface of the first interfacial insulating layer 24 to an upper surface of the mask layer 39.

The first gate spacers 40 may be on both (i.e. opposite) side surfaces of the first gate structure GS_{N}. The first gate spacers 40 may insulate the first source/drain regions 2a and the first gate structure GS_{N} from each other. The first gate spacers 40 may be formed of at least one of an oxide, a nitride, or an oxynitride, and may be formed of, for example, a low-k film.

The first source/drain regions 2a may be in the substrate 1 on both (i.e. opposite) sides of the first gate structure GS_{N}. The first source/drain regions 2a may include a plurality of impurity regions having different doping concentrations, but example embodiments are not limited thereto, and the shape of impurity regions included in the first source/drain regions 2a and the number of the regions may be varied.

The second circuit devices TR_{P} may be in a matrix in the PMOS region PR, and the second circuit devices TR_{P} may include a planar transistor in the well region 5 of the substrate 1, that is, the well region 5 including first conductivity-type impurities. The first conductivity-type impurities may be N-type impurities, and the second circuit devices TR_{P} may be PMOS transistors.

Each second circuit device TR_{P} may include a channel structure 23, second gate dielectric structures 24, 25_{P}, a first work function tuning layer 32, a second gate structure GS_{P} including a second gate electrode structure GE_{P}, second source/drain regions 2b, and gate spacers 40.

The channel structure 23 may include a semiconductor device material having a smaller band gap than the substrate 1 on the substrate 1. For example, when substrate 1 may include silicon, channel structure 23 may include silicon-germanium (SiGe).

The second gate dielectric structures 24, 25_{P} may be on the channel structure 23, and may include a second interfacial insulating layer 24 and a second gate dielectric layer 25_{P}.

The second interfacial insulating layer 24 may be on an upper surface of the channel structure 23, may include the same material as the first interfacial insulating layer 24 of the first gate structure GS_{N}, and may have the same first thickness T1 as that of the first interfacial insulating layer 24. The second interfacial insulating layer 24 may include oxide or a nitride, and may include a silicon oxide film (SiO₂).

The second gate dielectric layer 25_{P} may be on the second interfacial insulating layer 24 and may include a high-κ material. The high-κ material may indicate a dielectric material having a dielectric constant higher than that of a silicon oxide film (SiO₂). The second gate dielectric layer 25 may include at least one of hafnium oxide, hafnium silicon oxide, zirconium oxide, zirconium silicon oxide, tantalum oxide, titanium oxide, barium titanium oxide, lithium oxide, aluminum oxide, or lead zinc niobate.

The second gate dielectric layer 25_{P} may have the second thickness T2 the same as a thickness of the first gate dielectric layer 25_{N}, and differently from the first gate dielectric layer 25_{N}, the second gate dielectric layer 25_{P} may not include impurities therein.

Accordingly, the layer may not contain any material from the group 3 elements of the transition metals, which are high reactivity metal materials, such as scandium (Sc), yttrium (Y), actinium (Ac) and lanthanum (La), or from group 2 elements of a 5th period or lower, such as strontium (Sr), and may be hafnium oxide (HfO).

Accordingly, the second gate dielectric layer 25_{P} may not generate a dipole when an external voltage is applied to the second gate dielectric layer 25_{P}, such that the work function of the second gate electrode structure GE_{P} of the PMOS transistor may not decrease.

In the case of the PMOS transistor, differently from the NMOS transistor, a work function thereof may need to maintain a large value, such that the energy band may not be tilted at a conduction band level of the semiconductor device lowered by the channel structure 23, and accordingly, a large work function may be maintained.

The second gate electrode structure GE_{P} may be on the second gate dielectric layer 25_{P}. The lower conductive layer 30 may be on the second gate dielectric layer 25_{P}. The lower conductive layer 30 may be a metal base layer and may include metal or metal nitride. The lower conductive layer 30 may include titanium nitride, tantalum nitride, or a combination thereof. The lower conductive layer 30 may include titanium nitride (TiN) and may have a 5-1 thickness T5a.

A diffusion barrier (e.g. diffusion barrier layer) 31 may be on the lower conductive layer 30. The diffusion barrier 31 may have a 5-2 thickness T5b smaller than the 5-1 thickness T5a, may include the same material as the lower conductive layer 30, and may be doped with impurities.

The diffusion barrier 31 may be doped to a predetermined depth in an upper region of the lower conductive layer 30, thereby changing a crystal structure and preventing high reactivity metal materials of the first work function tuning layer 32 of the upper portion from being diffused into the second gate dielectric layer 25_{P} therebelow or into the lower conductive layer 30.

The diffusion barrier 31 may include impurities such as carbon (C), silicon (Si), and germanium (Ge) in the same material layer as the lower conductive layer 30, and may include silicon (Si). A concentration of impurities of the diffusion barrier 31 may satisfy 2% or more, and the sum of the 5-2 thickness T5b of the diffusion barrier 31 and the 5-1 thickness T5a of the lower conductive layer 30 in a lower portion may satisfy the fifth thickness T5. The fifth thickness T5 may be formed to be less than or equal to a predetermined thickness, and the predetermined thickness may be determined depending on a process threshold of a height deviation between the first gate structure GS_{N} and the second gate structure GS_{P}.

The diffusion barrier 31 may have a concentration gradient of impurities from an upper surface to the lower conductive layer 30 in a lower portion. Specifically, the concentration of impurities from the upper surface to the lower surface of the diffusion barrier 31 in contact with the lower conductive layer 30 may have a concentration gradient such that the concentration may converge to 0.

The second work function tuning layer 32 may be on the diffusion barrier 31. The second work function tuning layer 32 may be a metal oxide film or a metal oxynitride film including at least one metal of a group 3 element among transition metals which are high reactivity metal materials, for example, scandium (Sc), yttrium (Y), actinium (Ac), and lanthanum (La), or a metal oxide film or metal oxynitride film containing at least one metal of group 2 strontium (Sr) of period 5 or less. The second work function tuning layer 32 may include substantially the same material as the first work function tuning layer 32 of the first circuit device TR_{N}, but the concentration of the included high reactivity metal material may be different. Specifically, the high reactivity metal material in the second work function tuning layer 32 may be contained as a second concentration, and the second concentration may maintain a concentration higher than the first concentration of the first work function tuning layer 32. The second work function tuning layer 32 may have substantially the fourth thickness T4 the same as the first work function tuning layer 32.

The second work function tuning layer 32 may have at least two layer structures. That is, the layer may include a lower work function tuning layer 32a in contact with the diffusion barrier 31 and including impurities the same as the impurities of the diffusion barrier 31, and an upper work function tuning layer 32b not including impurities on the lower work function tuning layer 32.

The region from the diffusion barrier 31 to the region in which impurities are present may be defined as the lower work function tuning layer 32a, and a concentration gradient of impurities may be formed from an upper surface of the diffusion barrier 31 to a lower surface of the upper work function tuning layer 32b. Specifically, the concentration of impurities may be gradually reduced from the lower surface of the lower work function tuning layer 32a in contact with the diffusion barrier 31 to the lower surface of the upper work function tuning layer 32b, that is, the upper surface of the lower work function tuning layer 32a, such that the concentration gradient may converge to 0. Accordingly, the upper work function tuning layer 32b may not contain any impurities, for example, silicon, and may be only formed of metal oxide or metal oxynitride.

A thickness of the upper work function tuning layer 32b may occupy most of the entire third thickness T3, and the lower work function tuning layer 32a may include a relatively small thickness. That is, the impurities may not have a large diffusion degree from the lower surface of the lower work function tuning layer 32a, and diffusion may occur only in a portion of the region close to the lower surface.

Substantially the second gate electrode structure GE_{P} may be on the second work function tuning layer 32.

The second gate electrode structure GE_{P} may include at least double layers, but example embodiments are not limited thereto. The gate electrode structure GE_{P} may include a first conductive layer 33, a second conductive layer 35, and a third conductive layer 37, stacked in a vertical direction on the second work function tuning layer 32.

The first conductive layer 33 may be a metal layer, may include titanium nitride (TiN) or TSN (Ti—Si—N), and may have the same thickness as that of the first conductive layer 33 of the first circuit device TR_{N}. The second conductive layer 35 may include polysilicon, but example embodiments are not limited thereto. The third conductive layer 37 may include a metal material different from that of the first conductive layer 33, and may include tungsten (W), for example, but example embodiments are not limited thereto.

An ohmic contact layer 38 may be further included between the second conductive layer 35 and the third conductive layer 37, and the ohmic contact layer 38 may include titanium nitride (TiN), tantalum nitride (TaN), or the like, but example embodiments are not limited thereto. The ohmic contact layer 38 may have a thickness significantly smaller than the thicknesses of the second conductive layer 35 and the third conductive layer 37.

The stack structures of the first to third conductive layers 33, 35, and 37 and the ohmic contact layer 38 may be the same in the first circuit device TR_{N} and the second circuit device TR_{P}. Accordingly, the thicknesses of the first to third conductive layers 33, 35, and 37 in the two circuit devices TR_{N} and TR_{P} may be substantially the same.

A mask layer 39 may further be included in an upper portion of the second gate electrode structure GE_{P}. The mask layer 39 may include silicon nitride, silicon oxynitride, or the like.

A vertical length from the upper surface of the second gate electrode structure GE_{P} to the substrate 1 may have a second height h2. The second height h2 may be defined as the total thickness from the channel structure 23 to the mask layer 39, and may be greater than the first height h1 of the first circuit device TR_{N}. This because the second circuit device TR_{P} may further include a channel structure 23, a lower conductive layer 30, and a diffusion barrier 31, differently from the first circuit device TR_{N}.

The second gate spacers 40 may be on both (i.e. opposite) side surfaces of the second gate structure GS_{P}. The second gate spacers 40 may insulate the second source/drain regions 2b and the second gate structure GS_{P} from each other. The second gate spacers 40 may be formed of at least one of an oxide, a nitride, or an oxynitride, and may be formed of, for example, a low-k film.

The second source/drain regions 2b may be in the substrate 1 on both (i.e. opposite) sides of the second gate structure GS_{P}. The second source/drain regions 2b may include a plurality of impurity regions having different doping concentrations, but example embodiments are not limited thereto, and the shape of impurity regions included in the second source/drain regions 2b and the number of the regions may be varied.

The first circuit devices TR_{N} may be in the NMOS region NR as NMOS transistors, and the second circuit devices TR_{P} may be in the PMOS region PR as PMOS transistors on the substrate 1, and various circuits may be implemented through plugs and interconnections for electrical connection with gate structures GS_{N} and GS_{P} and source/drain regions 2a and 2b, respectively.

The first circuit devices TR_{N} and the second circuit devices TR_{P} may be planar transistors, and when the circuit devices have different conductivity types, the same stacking process may be applied, and a portion of layers may be changed and may be configured to be controlled by different work functions.

Specifically, when the NMOS transistor and the PMOS transistor include gate dielectric layers 25_{N} and 25_{P} of the same material on the same substrate 1, a work function of the NMOS transistor may be implemented to be relatively small, and a work function of the PMOS transistor may be implemented to be relatively large such that the movement of each carrier may be induced and configured to be controlled individually.

To this end, the gate dielectric layers 25_{N} and 25_{P} of the NMOS transistor and the PMOS transistor may be formed to include the same high-κ material, for example, hafnium oxide, and a work function tuning layer 32 inducing a dipole on the first gate dielectric layer 25_{N} in the NMOS transistor and lowering the work function may be included. The work function tuning layer 32 may include a high reactivity metal material, for example, an oxide of a metal base including lanthanum, and the high reactivity metal material may be diffused into the first gate dielectric layer 25_{N} in a lower portion by heat treatment.

When high reactivity metal materials are diffused into the first gate dielectric layer 25_{N} of the NMOS transistor, the materials may be easily combined with oxygen in the first gate dielectric layer 25_{N} and may form lanthanum-hafnium oxide, and such lanthanum-hafnium oxide may attract silicon atoms when silicon oxide is the interfacial insulating layer 24 therebelow.

Accordingly, a lower surface of the first gate dielectric layer 25_{N} may have a (−) polarity on an interfacial surface between the first interfacial insulating layer 24 and the first gate dielectric layer 25_{N}, an upper surface of the first interfacial insulating layer 24 may have a (+) polarity, and a lower surface of the first interfacial insulating layer 24 may generate a dipole with (−) polarity.

When a dipole is induced in the gate dielectric structure 24 and 25_{N} as above, an energy band may be tilted upwardly from the conduction band side. Accordingly, a work function of the gate electrode structure GE_{N} in an upper portion may be reduced, such that a threshold voltage Vth may be lowered, and a thickness of the inversion layer Tinv may be reduced, such that the equivalent oxide thickness EOT of the first gate dielectric structures 24 and 25_{N} may be sufficiently reduced.

When the same work function tuning layer 32 is in the PMOS transistor and provides a high reactivity metal material to the second gate dielectric layer 25_{P} in a lower portion, the work function of the PMOS transistor may be lowered. In example embodiments, even when the work function tuning layer 32 is in the PMOS transistor, by including a lower conductive layer 30 and a diffusion barrier 31 between the second gate dielectric layer 25_{P} and the second work function tuning layer 32, diffusion of the high reactivity metal material from the second work function tuning layer 32 downwardly may be prevented.

In the PMOS transistor, by disposing the lower conductive layer 30, which may be a metal nitride, the work function may be increased, and by blocking diffusion of high reactivity metal materials of the second work function tuning layer 32 by the lower conductive layer 30 and the second gate dielectric layer 25_{P} of the lower portion thereof by the diffusion barrier 31, decrease of the work function may be prevented and the increase of flat band voltage Vfb may be prevented. Since the thickness of the lower conductive layer 30 may be reduced by the diffusion barrier 31, a height difference between the PMOS transistor and the NMOS transistor may be reduced.

The NMOS transistor and the PMOS transistor may be simultaneously formed only by patterning the entire gate structure GS_{N} and GS_{P} without patterning the second work function tuning layer 32 including a relatively unstable material.

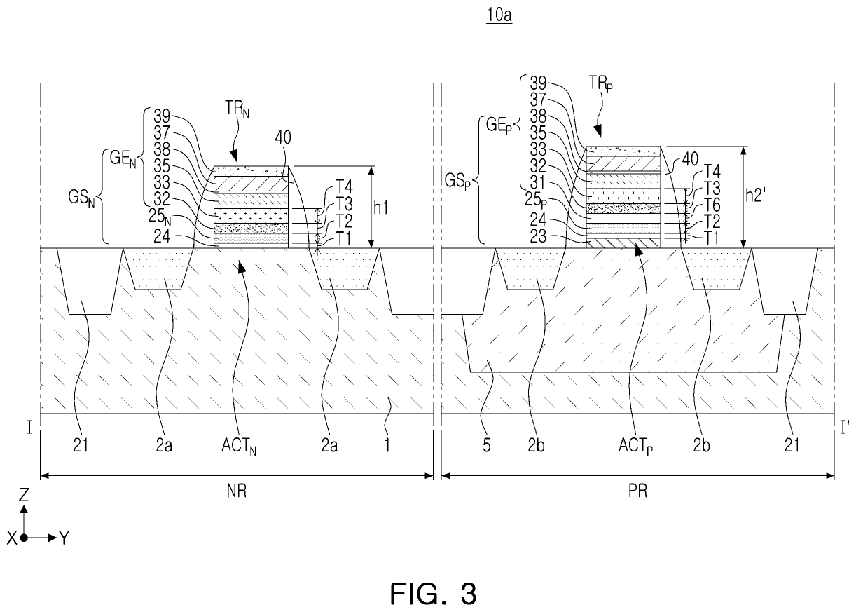

Hereinafter, example embodiments will be described with reference to FIGS. 3 to 5.

Referring to FIG. 3, an integrated circuit device 10a may be the same as the integrated circuit device 10 in FIG. 2 other than the configuration in which the diffusion barrier 31 is in direct contact with the second gate dielectric layer 25_{P} without the lower conductive layer 30.

In the integrated circuit device 10a, the diffusion barrier 31 may be directly on the second gate dielectric layer 25_{P}. The diffusion barrier 31 may include a material including impurities such as silicon, carbon, or germanium in the metal base nitride, and may have a state in which the entirety of impurities are included from an upper surface to a lower surface, and a concentration of the impurities from the lower surface to the upper surface may increase. For example, the diffusion barrier 31 may include titanium-silicon oxide, and when silicon atoms are combined in titanium oxide, a crystal structure may exhibit an amorphous structure, such that a strong diffusion prevention may be implemented as compared to a general titanium nitride film having a polycrystalline structure. The term “amorphous structure” may be used herein to specify patterns, layers, interfaces, or materials in an amorphous state where the structural arrangement lacks periodic arrangement or long-range order. Likewise, when patterns, layers, interfaces, or materials are referred to herein as having or exhibiting an amorphous structure, a non-crystalline arrangement of atoms and/or molecules is present.

When the diffusion barrier 31 is in direct contact with the second gate dielectric layer 25_{P} without the lower conductive layer 30, a high reactivity metal material of the second work function tuning layer 32 may be partially contained in the second gate dielectric layer 25_{P}. However, even in this case, by having a value significantly lower than the concentration of the high reactivity metal material in the first gate dielectric layer 25_{N}, reduction of the work function may be prevented.

The diffusion barrier 31 may have a sixth thickness T6 greater than a thickness of the diffusion barrier 31 in FIG. 2, and may have a thickness smaller than the 5-1 thickness T5a of the lower conductive layer 30 in FIG. 2. Accordingly, a step difference between the height h2′ of the PMOS transistor and the height h1 of the NMOS transistor may be reduced.

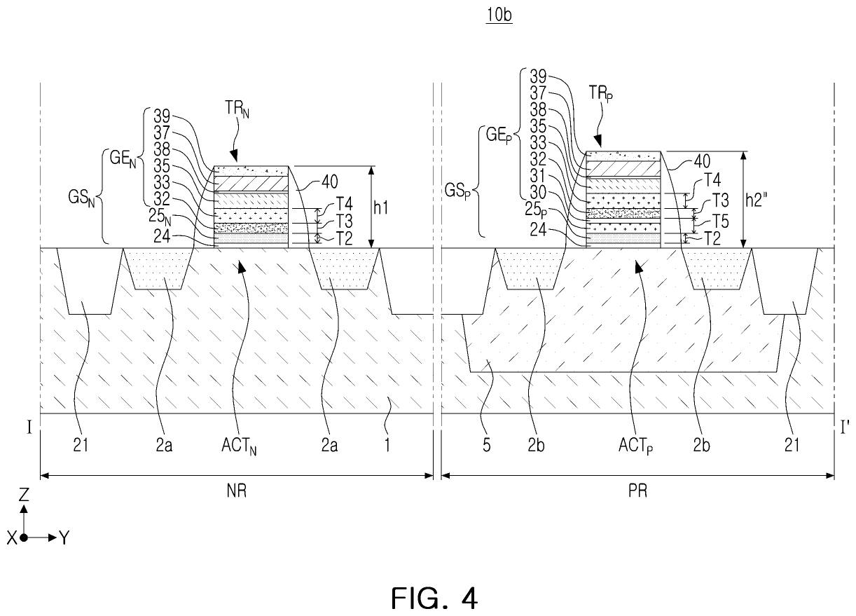

Referring to FIG. 4, an integrated circuit device 10b may be the same as the integrated circuit device 10 in FIG. 2 other than the configuration in which the interfacial insulating layer 24 is in direct contact with the substrate 1 without the channel structure 23.

The integrated circuit device 10b may not include a channel structure 23 on the substrate 1 in the second circuit device TR_{P}. That is, when the work function of the PMOS transistor is configured to control thicknesses of the interfacial insulating layer 24, the high-k gate dielectric layer 25_{P}, the lower conductive layer 30 and the first conductive layer 33 in an upper portion from the silicon substrate 1, a channel region ACT_{P} may be formed in a region with the source/drain region 2b of the substrate 1 without a channel structure 23 as illustrated in FIG. 4.

In this case, when no channel structure 23 is provided, the thicknesses of the lower conductive layer 30 and the first conductive layer 33 included in the second gate structure GS_{P} may be greater than in FIG. 2, but the step difference h2″−h1 with the NMOS transistor may be reduced due to the absence of the channel structure 23.

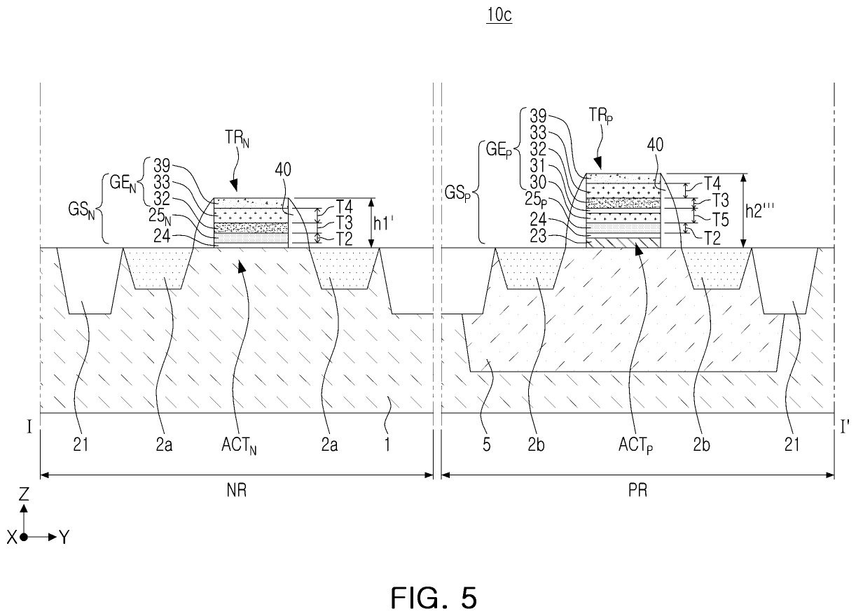

Referring to FIG. 5, an integrated circuit device 10c may be the same as the integrated circuit device 10 in FIG. 2 other than the configuration in which the mask layer 39 is in direct contact with the first conductive layer 33 without the second conductive layer 35 to the third conductive layer 37.

The integrated circuit device 10c may be formed to have a single layer of conductive material forming the gate electrode structure GE_{N} and GE_{P}. That is, in the first circuit device TR_{N}, only the first conductive layer 33 having the fourth thickness T4 may function as the gate electrode. In the second circuit device TR_{P}, the lower conductive layer 30 having the 5-1 thickness T5a and the first conductive layer 33 having the fourth thickness T4 may be synthesized and may function as the gate electrode. As described above, by adjusting the work function in the lower portion, a gate electrode structure GE_{N} and GE_{P} formed in a single layer or material layers may be formed instead of a multilayer gate electrode structure GE_{N} and GE_{P}.

As described above, when the second conductive layer 35 to the third conductive layer 37 are both removed, the first height h1′ of the first circuit device TR_{N} may be lower than the first height h1 of the first circuit device TR_{N} in FIG. 2, and the second height h2′″ of the second circuit device TR_{P} may also be lower than the second height h2 of the second circuit device TR_{P} in FIG. 2.

The various first circuit devices TR_{N} and the second circuit devices TR_{P} illustrated in FIGS. 1 to 5 may be applied to a circuit design of various integrated circuit devices.

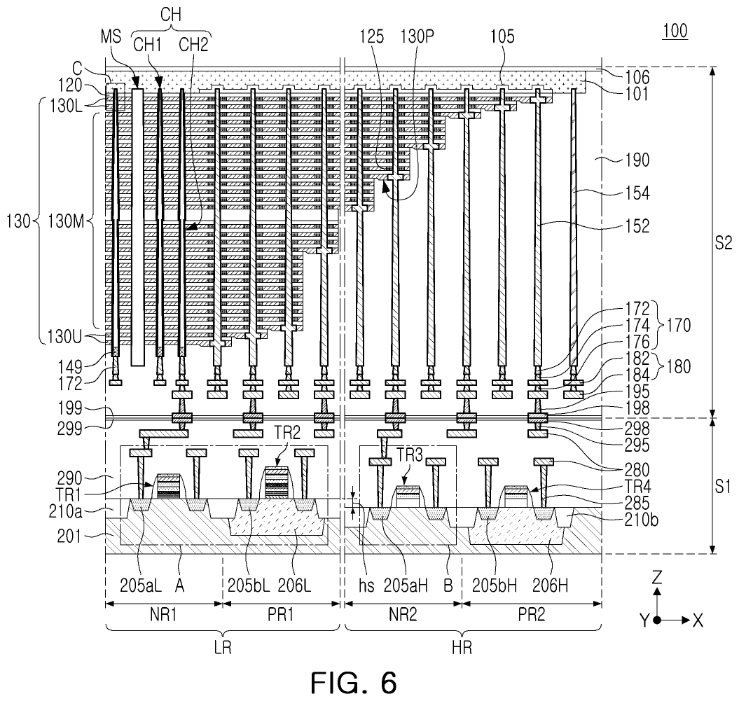

Hereinafter, an example in which the integrated circuit devices in FIGS. 1 to 5 are applied to a portion of a peripheral circuit structure of a memory device will be described with reference to FIGS. 6 to 8.

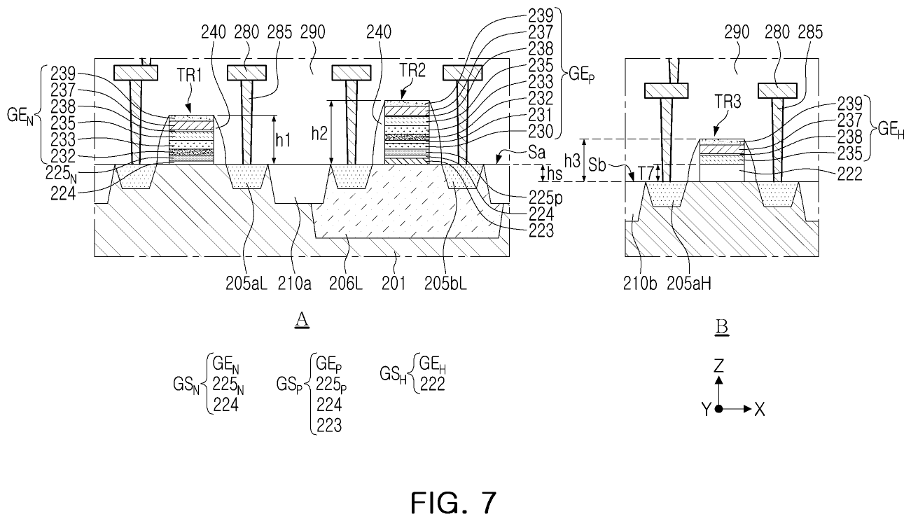

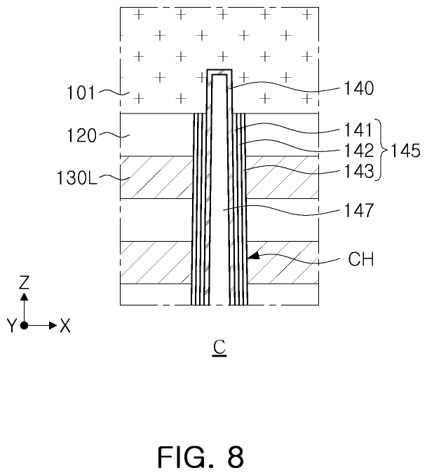

FIGS. 6 to 8 illustrate an integrated circuit device according to example embodiments. FIG. 6 is a cross-sectional view illustrating an integrated circuit device according to example embodiments, and FIGS. 7 and 8 are enlarged views illustrating an integrated circuit device in FIG. 6 according to example embodiments.

Referring to FIGS. 6 to 8, an integrated circuit device 100 may include first and second substrate structures S1 and S2 bonded to each other vertically. The first substrate structure S1 may include a peripheral circuit region, and the second substrate structure S2 may include a memory cell region.

The first substrate structure S1 may have a low-voltage device region LR and a high-voltage device region HR. The low-voltage device region LR may be defined as a region in which circuit devices are configured to be controlled with a relatively low operating voltage, and the high-voltage device region HR may be defined as a region in which circuit devices are configured to be controlled with a relatively high operating voltage.

The first substrate structure S1 may include a substrate 201, device isolation layers 210a and 210b in the substrate 201, first circuit devices TR1 and second circuit devices TR2 on the substrate 201 in the low-voltage device region LR, third circuit devices TR3 and fourth circuit devices TR4 on the substrate 201 in the high-voltage device region HR, peripheral region insulating layer 290 on the upper surface of substrate 201, contact plugs 285 on the substrate 201, circuit interconnection lines 280, first bonding vias 295, first bonding pads 298 and a first bonding insulating layer 299.

The first substrate structure S1 may include a first well region 206L in the low-voltage device region LR, first and second source/drain regions 205aL and 205bL, a second well region 206H in the high-voltage device region HR, and first and second source/drain regions 205aH and 205bH.

The substrate 201 may have an upper surface extending in the X-direction and the Y-direction.

The substrate 201 may include a first upper surface Sa in the low-voltage device region LR and a second upper surface Sb in the high-voltage device region HR, and the second upper surface Sb may be at a level lower than a level of the first upper surface Sa in the Z-direction by a substrate step difference hs. Accordingly, a starting point of the gate structure GS_{H} of the high-voltage device region HR may be at a lower level.

The substrate 201 may include an integrated circuit device material, for example, a group IV integrated circuit device, a group III-V compound integrated circuit device, or a group II-VI compound integrated circuit device. For example, the substrate 201 may be provided as a single-crystal silicon bulk wafer.

CMOS transistors may be in each of the low-voltage device region LR and the high-voltage device region HR, and in the substrate 201, the first well region 206L and the second well region 206H may be disposed such that transistors of different conductivity types may be in each of the device regions LR and HR. When the substrate 201 is a P-type semiconductor device, the first well region 206L and the second well region 206H may be N-type wells doped with N-type impurities.

Accordingly, a portion other than the first well region 206L and the second well region 206H may be defined as first device regions NR1 and NR2 with NMOS transistors, and a portion of the first well region 206L and the second well region 206H may be defined as second device regions PR1 and PR2 with PMOS transistors. When the conductivity-type of the substrate 201 is opposite, a conductivity-type of each region may be opposite.

A low-voltage device region LR and a high-voltage device region HR may define active regions by forming device isolation layers 210a and 210b, respectively. The device isolation layers 210a and 210b may be formed, for example, by a shallow trench isolation (STI) process. In example embodiments, the layout and depth of the device isolation layers 210a and 210b may be varied. The device isolation layers 210a and 210b may be formed of an insulating material. The device isolation layers 210a and 210b may be, for example, oxides, nitrides, or a combination thereof.

First and second source/drain regions 205aL, 205bL, 205aH and 205bH including impurities may be in a portion of the active regions.

The low-voltage device region LR may include a first device region NR1 and a second device region PR1, and the high-voltage device region HR may also include a first device region NR2 and a second device region PR2.

Accordingly, the first and second source/drain regions 205aL and 205bL in the low-voltage device region LR may be in the first device region NR1 and the second device region PR1, respectively, and may be doped with impurities of different conductivity-types, and the first and second source/drain regions 205aH and 205bH in the high-voltage device region HR may be in the first device region NR2 and the second device region PR2, respectively, and may be doped with impurities of different conductivity-types.

The first source/drain regions 206aL and 206aH in the first device regions NR1 and NR2 in the low-voltage device region LR and the high-voltage device region HR may be doped with the same impurities, and the second source/drain regions 206bL and 206bH in the second device regions PR1 and PR2 in the low-voltage device region LR and the high-voltage device region HR may be doped with the same impurities.

In the first substrate structure S1 of the integrated circuit device 100, the first device region NR1 and the second device region PR1 of the low-voltage device region LR may correspond to the first device region NR and the second device region PR of the integrated circuit device 10 in FIGS. 1 to 5 described above, respectively.

Accordingly, the first circuit device TR_{N}, which is an NMOS transistor in FIG. 2, may be the first circuit device TR1 of the low-voltage device region LR1, and the second circuit device TR_{P}, which is a PMOS transistor in FIG. 2, may be the second circuit device TR2 of the low-voltage device region LR1.

The first circuit devices TR1 of the low-voltage device region LR may be on an upper surface of the substrate 201 as illustrated in FIG. 2, may be configured as a planar transistor, and may include a first gate electrode structure GE_{N}, a first gate dielectric structure 224, 225_{N}, a first gate structure GS_{N} including a work function tuning layer 232, first source/drain regions 205aL, and first gate spacers 240.

The first gate dielectric structure 224, 225_{N} may include a first interfacial insulating layer 224, and a first gate dielectric layer 225_{N}.

The first interfacial insulating layer 224 may be on the first upper surface Sa of the substrate 201, and may be the same as the first interfacial insulating layer 24 in FIG. 2, and the first gate dielectric layer 225_{N} may be the same as the first gate dielectric layer 25_{N} in FIG. 2.

A first work function tuning layer 232 may be on the first gate dielectric layer 225_{N}, and the first work function tuning layer 232 may be the same as the first work function tuning layer 32 in FIG. 2, may include an oxide or nitride including a high reactivity metal material, and may include lanthanum oxide.

A substantial first gate electrode structure GE_{N} may be on the first work function tuning layer 232.

The first gate electrode structure GE_{N} may include at least two layers, but example embodiments are not limited thereto. The first gate electrode structure GE_{N} may include a first conductive layer 233, a second conductive layer 235, and a third conductive layer 237 stacked in a vertical direction on the first work function tuning layer 232. Each of the conductive layers 233, 235, and 237 may be the same as the first to third conductive layers 33, 35, and 37 in FIG. 2, respectively.

An ohmic contact layer 238 may be further included between the second conductive layer 235 and the third conductive layer 237, and the ohmic contact layer 238 may include titanium nitride (TiN), tantalum nitride (TaN), or the like, but example embodiments are not limited thereto. A mask layer 239 may be further included in an upper portion of the first gate electrode structure GE_{N}. The mask layer 239 may include silicon nitride, silicon oxynitride, or the like.

A vertical length from an upper surface of the first gate structure GS_{N} to the substrate 201 may have a first height h1. The first height h1 may be defined as the sum of the thicknesses from the first interfacial insulating layer 224 to the mask layer 239.

The first gate spacers 240 may be on both (i.e. opposite) side surfaces of the first gate structure GS_{N}. The first gate spacers 240 may insulate the first source/drain regions 205aL and the first gate structure GS_{N} from each other. The first gate spacers 240 may be formed of at least one of oxide, nitride, or oxynitride, and may be formed of, for example, a low-k film.

The first source/drain regions 205aL may be in the substrate 201 on both (i.e. opposite) sides of the first gate structure GS_{N}. The first source/drain regions 205aL may include a plurality of impurity regions having different doping concentrations.

The second circuit devices TR2 of the low-voltage device region LR may be configured as a PMOS transistor as a planar transistor in the well region 206L of the substrate 201.

Each of the second circuit devices TR2 may include a channel structure 223, a second gate dielectric structure 224 and 225_{P}, a work function tuning layer 232, a second gate structure GS_{P} including a second gate electrode structure GE_{P}, second source/drain regions 205bL, and gate spacers 240.

The channel structure 223 may include a semiconductor device material having a band gap smaller than that of the substrate 201 on the first upper surface Sa of the substrate 201. For example, when the substrate 201 includes silicon, the channel structure may include silicon-germanium (SiGe).

The second gate dielectric structure 224 and 225_{P} may include a second interfacial insulating layer 224, a second gate dielectric layer 225_{P}, and may be the same as the second interfacial insulating layer 24 and the second gate dielectric layer 25_{P} in FIG. 2, respectively.

The second interfacial insulating layer 224 may be on an upper surface of the channel structure 223, may include the same material as a material of the first interfacial insulating layer 224, and may have the same thickness as a thickness of the first interfacial insulating layer 224. The second interfacial insulating layer 224 may include an oxide or nitride, and may include a silicon oxide film (SiO₂).

That is, the second gate dielectric layer 225_{P} may be on the second interfacial insulating layer 224, may include a high-κ material, and may include the same thickness as a thickness of the first gate dielectric layer 225_{N}, and differently from the first gate dielectric layer 225, the second gate dielectric layer 225_{P} may not include a high reactivity metal material, which is at least one metal among scandium (Sc), yttrium (Y), actinium (Ac), and lanthanum (La), as impurities therein. Accordingly, the layer may not contain at least one of scandium (Sc), yttrium (Y), actinium (Ac), or lanthanum (La), and may be hafnium oxide not containing lanthanum.

The lower conductive layer 230 may be on the second gate dielectric layer 225. The lower conductive layer 230 may be the same as the lower conductive layer 30 in FIG. 2, and the lower conductive layer 230 may include a metal base layer, preferably titanium nitride (TiN).

A diffusion barrier 231 may be on the lower conductive layer 230. The diffusion barrier 231 may be the same as the diffusion barrier 31 in FIG. 2. The diffusion barrier 231 may include the same material as a material of the lower conductive layer 230, and may be doped with impurities.

The diffusion barrier 231 may be doped to a predetermined depth in the upper region of the lower conductive layer 230 such that a crystal structure may be changed to exhibit an amorphous structure, thereby preventing the hyper-reactive materials of the work function tuning layer 232 of the upper portion from being diffused into the second gate dielectric layer 225 therebelow or into the lower conductive layer 230.

The diffusion barrier 231 may include impurities such as carbon, silicon, and germanium in the lower conductive layer 230, and may include silicon. A concentration of impurities of the diffusion barrier 231 may satisfy 2% or more, and the diffusion barrier 231 may have a thickness the same as or smaller than the thickness of the lower conductive layer 230 in a lower portion. A concentration gradient of impurities may be formed from an upper surface of the diffusion barrier 231 to a lower surface of the diffusion barrier 231, and a concentration of the impurities may decrease from the upper surface to the lower surface and may become 0% at the lower surface.

A second work function tuning layer 232 may be on the diffusion barrier 231. The second work function tuning layer 232 may be the same as the second work function tuning layer 32 in FIG. 2. The second work function tuning layer 232 may be a metal oxide film or a metal oxynitride film including at least one high reactivity metal material from among scandium (Sc), yttrium (Y), actinium (Ac), and lanthanum (La) or strontium (Sr), and may be a lanthanum oxide film (La₂O₃). The second work function tuning layer 232 may substantially include the same material as a material of the first work function tuning layer 232, but a concentration of the included high reactivity metal material may be different. Specifically, the high reactivity metal material in the second work function tuning layer 232 may be contained in a second concentration, and the second concentration may maintain a concentration higher than the first concentration of the first work function tuning layer 232. The second work function tuning layer 232 may have substantially the same thickness as that of the first work function tuning layer 232.

The second work function tuning layer 232 may be in contact with the diffusion barrier 231, may include impurities the same as those of diffusion barrier 231, and may not include impurities in an upper portion. A concentration gradient of impurities may be formed from an upper surface of the diffusion barrier 231 to an upper surface of the second work function tuning layer 232. The upper portion of the work function tuning layer 232 may not include any impurities, for example, silicon, and may be formed only of a metal oxide or a metal oxynitride.

A substantial second gate electrode structure GE_{P} may be on the second work function tuning layer 232.

The second gate electrode structure GE_{P} may include at least two layers, but example embodiments are not limited thereto. The second gate electrode structure GE_{P} may include a first conductive layer 233, a second conductive layer 235, and a third conductive layer 237, stacked in a vertical direction on the second work function tuning layer 232. The second gate electrode structure GE_{P} may correspond to each layer of the second gate electrode structure GE_{P} in FIG. 2, and the description thereof may not be provided.

The upper portion of the second gate electrode structure GE_{P} may further include a mask layer 239. The mask layer 239 may include silicon nitride, silicon oxynitride, or the like.

The vertical length from an upper surface of the second gate structure GS_{P} to the substrate 201 may have a second height h2. The second height h2 may be defined as a total thickness from the channel structure 223 to the mask layer 239, and may have a height greater than the first height h1 of the first circuit device TR1. This may be because the second circuit device TR2 may further include the channel structure 223, the lower conductive layer 230, and the diffusion barrier 231, differently from the first circuit device TR1.

The second gate spacers 240 may be on both (i.e. opposite) side surfaces of the second gate structure GS_{P}. The second source/drain regions 205bL may be in the first well region 206L of the substrate 201 on both (i.e. opposite) sides of the second gate structure GS_{P}.

As described above, the first circuit device TR_{N} and the second circuit device TR_{P} in FIG. 2 may correspond to the first circuit device TR1 and the second circuit device TR2 of the low-voltage device region LR in FIG. 6, respectively, and the detailed description thereof may not be provided.

The third circuit devices TR3 and the fourth circuit devices TR4 may be in the high-voltage device region HR of the integrated circuit device 100.

The third circuit devices TR3 may function as NMOS transistors on the second upper surface Sb of the high-voltage device region HR, and the fourth circuit devices TR4 may function as PMOS transistors on the second upper surface Sb of the high-voltage device region HR.

In FIGS. 6 and 7, the sizes, for example, the channel lengths, of the circuit devices TR3 and TR4 in the high-voltage device region HR may be the same as or similar to those of each circuit device TR1 and TR2 in the low-voltage device region LR, but example embodiments are not limited thereto, and the sizes, for example, the channel lengths, of the circuit devices TR3 and TR4 in the high-voltage device region HR may be larger.

The third circuit devices TR3 and the fourth circuit devices TR4 may be in conductivity-type regions, respectively, and at least one of the devices may be in the well region 206H. In FIG. 6, the substrate 201 may be configured as a P-type substrate 201, and the fourth circuit devices TR4 may be in the well region 206H doped with N-type impurities, but example embodiments are not limited thereto.

The third circuit devices TR3 and the fourth circuit devices TR4 may have the same stacking structure as the gate structure GS_{H} other than the configuration where the regions with the circuit devices have different conductivity-types.

That is, the third circuit devices TR3 and the fourth circuit devices TR4 may be configured as planar transistors, and may include the gate structure GS_{H} having a third height h3 from the substrate 201 on the second upper surface Sb, which is lower than the first upper surface Sa of the substrate 201 by the substrate step difference hs, a gate spacer 240, and third and fourth source/drain regions 205aH and 205bH. The third height h3 may be lower than the second height h2, and may be the same as or lower than the first height h1, but example embodiments are not limited thereto.

The gate structure GS_{H} may include a gate electrode structure GE_{H} including a gate dielectric layer 222, a lower conductive layer 235, and an upper conductive layer 237.

The gate dielectric layer 222 may include a low-k material, and may include a material such as an oxide or a nitride, for example a silicon oxide film (SiO₂). The gate dielectric layer 222 may have a thickness T7 greater than the thicknesses of the interfacial insulating layer 224 of the first circuit device TR1 and the second circuit device TR2 or the first and second gate dielectric layers 225_{N} and 225_{P}, and may have a thickness T7 substantially the same as the substrate step difference hs, but example embodiments are not limited thereto.

The gate electrode structure GE_{H} may be on the gate dielectric layer 222 and may include at least two layers, but example embodiments are not limited thereto. The gate electrode structure GE_{H} may include a lower conductive layer 235 and an upper conductive layer 237.

The lower conductive layer 235 may include polysilicon, but example embodiments are not limited thereto, and the lower conductive layer 235 may be formed of substantially the same material as a material of the second conductive layer 235 and may have the same thickness as a thickness of the second conductive layer 235. The upper conductive layer 237 may include a metal such as tungsten or aluminum, and may be formed of substantially the same material as a material of the third conductive layer 237 of the second circuit device TR2 and may have the same thickness as a thickness of the third conductive layer 237 of the second circuit device TR2. An ohmic contact layer 238 may be further included between the upper and lower conductive layers 235 and 237, and the ohmic contact layer 238 may include titanium nitride (TiN), tantalum nitride (TaN), or the like, but example embodiments are not limited thereto. The ohmic contact layer 238 may have a thickness significantly smaller than the thicknesses of the lower conductive layer 235 and the upper conductive layer 237.

A mask layer 239 may be further included in an upper portion of the gate electrode structure GE_{H}. The mask layer 239 may include silicon nitride, silicon oxynitride, or the like.

Accordingly, in the third and fourth circuit devices TR3 and TR4, the upper conductive layer 235, the ohmic contact layer 238 and the upper conductive layer 237 and the mask layer 239 may be on the first upper surface Sa of the substrate 201, and the level of the upper surface of the third and fourth circuit devices TR3 and TR4 may be on a level lower than the level of the upper surface of the first circuit device TR1 and the second circuit device TR2. Accordingly, even when the third and fourth circuit devices TR3 and TR4 include the thick gate dielectric layer 222, the devices may not have a height greater than those of the first and second circuit devices TR1 and TR2 due to the low second upper surface Sb of the substrate 201.

The gate spacers 240 may be on both (i.e. opposite) side surfaces of the gate structure GS_{H}. The third and fourth source/drain regions 205aH and 205bH may be in the substrate 201 on both (i.e. opposite) sides of the gate structure GS_{H}.

The gate spacers 240 may be formed of at least one of an oxide, a nitride, or an oxynitride, for example, a low-k film.

The third and fourth source/drain regions 205aH and 205bH may be in the substrate 201 on both (i.e. opposite) sides of the gate structure GS_{H} and may include impurities.

The peripheral region insulating layer 290 may be on the first and second upper surfaces Sa and Sb of the substrate 201 on the first, second, third, and fourth circuit devices TR1, TR2, TR3, and TR4. The peripheral region insulating layer 290 may include a plurality of insulating layers formed at different processes. The peripheral region insulating layer 290 may be formed of an insulating material, for example, at least one of oxide, nitride, or oxynitride.

The contact plugs 285 may penetrate the peripheral region insulating layer 290 and may be connected to first, second, third, and fourth source/drain regions 205aL and 205bL, 205aH, and 205bH. A portion of the contact plugs 285 may penetrate the peripheral region insulating layer 290 and may be connected to first second gate electrode structures GE_{N} and GE_{P} and gate electrode structures GE_{H}.

Each of the contact plugs 285 may have an inclined side surface such that a width of an upper surface may be greater than a width of a lower surface. Upper ends of the contact plugs 285 may be substantially at the same level, but example embodiments are not limited thereto.

Each of the contact plugs 285 may have a cylindrical shape. The contact plugs 285 may include a conductive material, for example, at least one of a semiconductor device material, a metal-semiconductor device compound, or a metal material such as tungsten (W), cobalt (Co), molybdenum (Mo), copper (Cu), ruthenium (Ru), and aluminum (Al), and may further include a diffusion barrier. The contact plugs 285 and the circuit interconnection lines 280 may be on upper surface Sa and Sb of the substrate 201 and may be connected to each other.

A backside interconnection structures and a backside insulating layer may be on the backside of the substrate 201, and at least a portion of the backside interconnection structures may form a backside power delivery network (BSPDN), but example embodiments are not limited thereto.

The first bonding vias 295, the first bonding pads 298, and the first bonding insulating layer 299 may be included in the first bonding structure and may be on the uppermost circuit interconnection lines 280. The first bonding vias 295 may have a cylindrical shape, and the first bonding pads 298 may have a line shape. Upper surfaces of the first bonding pads 298 and upper surfaces of the first bonding insulating layer 299 may be exposed to an upper surface of the first substrate structure S1. The first bonding vias 295 and the first bonding pads 298 may provide an electrical connection path between the first substrate structure S1 and the second substrate structure S2. A portion of the first bonding pads 298 may not be connected to the circuit interconnection line 280 in a lower portion and may be only for bonding. The first bonding vias 295 and the first bonding pads 298 may include a conductive material, for example, copper (Cu). The first bonding insulating layer 299 may be positioned around the first bonding pads 298. The first bonding insulating layer 299 may also function as a diffusion barrier of the first bonding pads 298 and may include at least one of, for example, SiN, SiON, SiCN, SiOC, SiOCN, or SiO₂.

The second substrate structure S2 may include a plate layer 101, gate electrodes 130 stacked on a lower surface of the plate layer 101, interlayer insulating layers 120 alternately stacked with the gate electrodes 130, channel structures CH penetrating the gate electrodes 130, isolation regions MS penetrating the gate electrodes 130 and extending in one direction, first cell contact plugs 152 connected to the gate electrodes 130, and second cell contact plugs 154 electrically connected to the plate layer 101. The second substrate structure S2 may further include a cover insulating layer 105, a passivation layer 106, contact insulating layers 125, cell upper contacts 170, cell interconnection lines 180, and cell region insulating layers 190. The second substrate structure S2 may further include second bonding vias 195, second bonding pads 198, and second bonding insulating layer 199 as a second bonding structure.

The plate layer 101 may have an upper surface extending in the X-direction and the Y-direction. The plate layer 101 may function as a common source line of the integrated circuit device 100. The plate layer 101 may include a conductive material. For example, the plate layer 101 may include a semiconductor device material, such as a group IV semiconductor device, a group III-V compound semiconductor device, or a group II-VI compound semiconductor device. For example, the group IV semiconductor device may include silicon, germanium, or silicon-germanium. The plate layer 101 may further include impurities. The plate layer 101 may be provided as a polycrystalline semiconductor device layer, such as a polycrystalline silicon layer, or an epitaxial layer. In some example embodiments, the plate layer 101 may include a plurality of conductive layers which may be vertically stacked.

The gate electrodes 130 may be vertically stacked and spaced apart from each other on the lower surface of the plate layer 101 and may form a stack structure together with the interlayer insulating layers 120. The stack structure may be vertically stacked and may include lower and upper stack structures surrounding first and second channel structures CH1 and CH2, respectively. However, in example embodiments, the stack structure may be formed as a single stack structure.

The gate electrodes 130 may include at least one lower gate electrode 130L forming a gate of a ground select transistor, memory gate electrodes 130M forming a plurality of memory cells, and upper gate electrodes 130U forming gates of string select transistors. Here, the terms “lower” and “upper” of the lower and upper stack structures, the lower gate electrode 130L, and the upper gate electrodes 130U may be denoted with respect to the direction during the manufacturing process. The number of memory gate electrodes 130M included in memory cells may be determined depending on capacity of the integrated circuit device 100. In example embodiments, the number of each of the upper and lower gate electrodes 130U and 130L may be 1 to 4 or more, and may have the same or different structure as a structure of the memory gate electrodes 130M. In example embodiments, the gate electrodes 130 may further include a gate electrode 130 below the upper gate electrodes 130U and/or on the lower gate electrode 130L and forming an erase transistor used for an erase operation using gate induced drain leakage (GIDL) phenomenon. A portion of the gate electrodes 130, for example, the memory gate electrodes 130M adjacent to the upper or lower gate electrode 130U and 130L, may be dummy gate electrodes.

The gate electrodes 130 may be stacked vertically spaced apart from each other, and may extend with different lengths in at least one direction, for example, the Y-direction, and may form a step difference structure in a staircase form. The gate electrodes 130 may also have a step difference structure in the X-direction. By the step difference structure, among the gate electrodes 130, the gate electrode 130 in the upper portion may extend further than the gate electrode 130 in a lower portion, and the gate electrodes 130 may have regions in which lower surfaces are exposed from the interlayer insulating layers 120 and other gate electrodes 130, and the regions may be referred to as pad regions 130P. The gate electrodes 130 may be connected to the first cell contact plugs 152 in the pad regions 130P. The gate electrodes 130 may have an increased thickness in the pad regions 130P.

The gate electrodes 130 may include a metal material, such as tungsten (W). In example embodiments, the gate electrodes 130 may include polycrystalline silicon or a metal silicide material. In example embodiments, the gate electrodes 130 may further include a diffusion barrier, and for example, the diffusion barrier may include tungsten nitride (WN), tantalum nitride (TaN), titanium nitride (TiN), or a combination thereof.

Interlayer insulating layers 120 may be between the gate electrodes 130. The interlayer insulating layers 120 may also be spaced apart from each other in a direction perpendicular to a lower surface of the plate layer 101 and may extend in the Y-direction, similarly to the gate electrodes 130. The interlayer insulating layers 120 may include an insulating material, such as silicon oxide or silicon nitride.

Each of the channel structures CH may be configured as a memory cell string and may be spaced apart from each other in rows and columns on the lower surface of the plate layer 101. The channel structures CH may form a grid pattern in the plan view or may be in a zigzag pattern in one direction. The channel structures CH may have a columnar shape and may have an inclined side surface such that a width may decrease toward the plate layer 101 depending on an aspect ratio.

Each of the channel structures CH may have a form in which the first and second channel structures CH1, CH2 penetrating the lower and upper stack structures of the gate electrodes 130, respectively, are connected to each other, and may have a bent portion due to a difference or change in width in the connection region. However, in example embodiments, the number of the channel structures stacked in the Z-direction may be varied.

Each of the channel structures CH may include a channel layer 140 in the channel hole, a gate dielectric layer 145, a channel filling insulating layer 147, and a channel pad 149. The channel layer 140 may be formed in an annular shape surrounding the channel filling insulating layer 147 therein, but in example embodiments may also have a columnar shape such as a cylinder or a prism without the channel filling insulating layer 147. The channel layer 140 may include a semiconductor device material such as polycrystalline silicon or single crystal silicon. The channel layer 140 may be exposed through an upper end and may be connected to the plate layer 101.

As illustrated in FIG. 8, the upper end of the channel layer 140 may be exposed from the channel dielectric layer 145 at an upper end of the channel structure CH. The upper end of the channel layer 140 may include an upper surface and an upper region of a side surface connected to the upper surface. The upper end of the channel layer 140 may be in direct contact with the plate layer 101 and may be surrounded by the plate layer 101. By this arrangement, the channel layer 140 may be physically and electrically connected to the plate layer 101.

The gate dielectric layer 145 may be between the gate electrodes 130 and the channel layer 140. Although not specifically illustrated, the gate dielectric layer 145 may include a tunneling layer, a charge storage layer, and a blocking layer stacked in order from the channel layer 140. The tunneling layer may tunnel charges into the charge storage layer and may include, for example, silicon oxide (SiO₂), silicon nitride (Si₃N₄), silicon oxynitride (SiON), or a combination thereof. The charge storage layer may be a charge trap layer or a floating gate conductive layer. The blocking layer may include, for example, silicon oxide (SiO₂), silicon nitride (Si₃N₄), silicon oxynitride (SiON), a high-κ dielectric material, or a combination thereof. In example embodiments, at least a portion of the gate dielectric layer 145 may extend horizontally along the gate electrodes 130.

The channel pad 149 may be only at a lower end of the second channel structure CH2 in a lower portion. The channel pads 149 may include, for example, doped polycrystalline silicon.

The channel layer 140, the gate dielectric layer 145, and the channel filling insulating layer 147 may be connected to each other between the first channel structure CH1 and the second channel structure CH2. An interlayer insulating layer 120 having a relatively large thickness may be between the first channel structure CH1 and the second channel structure CH2. However, the shape of the interlayer insulating layers 120 may be varied in example embodiments.

The isolation region MS may penetrate the gate electrodes 130 and may extend in one direction, for example, in the Y-direction. In FIG. 1, only one isolation region MS is illustrated, but a plurality of isolation regions MS may extend parallel to each other in the Y-direction and may be spaced apart from each other in the X-direction. The isolation region MS may penetrate the entire gate electrodes 130 stacked on the plate layer 101 and may be connected to the plate layer 101.

The isolation region MS may have a shape in which a width may decrease toward the plate layer 101 due to a high aspect ratio, but example embodiments are not limited thereto. The isolation region MS may include an insulating material, for example, silicon oxide, silicon nitride, or silicon oxynitride.

The first and second cell contact plugs 152 and 154 may extend in the Z-direction and may have inclined side surfaces such that a width may decrease toward the plate layer 101. Upper ends of the first and second cell contact plugs 152 and 154 may be on a lower surface of the plate layer 101, for example, on a lower surface or in the plate layer 101. The first and second cell contact plugs 152 and 154 may form a portion of a second interconnection structure in the second substrate structure S2.

The first cell contact plugs 152 may electrically connect the gate electrodes 130 to the first interconnection structure in the first substrate structure S1. The first cell contact plugs 152 may be physically and electrically connected to the gate electrodes 130 in respective pad regions 130P, and may apply an electrical signal to the gate electrodes 130. The first cell contact plugs 152 may penetrate the pad regions 130P of the gate electrodes 130. The first cell contact plugs 152 may penetrate the region in which the gate electrodes 130 form a staircase structure and may extend into the plate layer 101. The first cell contact plugs 152 may be electrically isolated from the plate layer 101 by a cover insulating layer 105. However, in some example embodiments, the first cell contact plugs 152 may be configured to not penetrate the gate electrodes 130. In this case, the first cell contact plugs 152 may extend to be connected to a lower surface or a lower portion of each of the gate electrodes 130.

The first cell contact plugs 152 may have a shape of horizontally extending in the pad regions 130P. The first cell contact plugs 152 may be spaced apart from the gate electrodes 130 above the pad regions 130P by contact insulating layers 125. The contact insulating layers 125 may surround a side surface of the first cell contact plug 152 and may be isolated from each other in the Z-direction. The contact insulating layers 125 may be at substantially the same level as a level of the gate electrodes 130, respectively. The contact insulating layers 125 may include an insulating material, for example, silicon oxide, silicon nitride, or silicon oxynitride.

The second cell contact plugs 154 may be in a region in which the gate electrodes 130 are not, for example, at an outer side of the gate electrodes 130. The second cell contact plug 154 may electrically connect the first to second circuit devices TR1 and TR2 of the first substrate structure S1 to the plate layer 101. The second cell contact plug 154 may penetrate a portion of the cell region insulating layer 190 and may extend into the plate layer 101.

The first and second cell contact plugs 152 and 154 may include a metal material, for example, tungsten (W), aluminum (Al), copper (Cu), tungsten nitride (WN), tantalum nitride (TaN), titanium nitride (TiN), or a combination thereof.

The cover insulating layer 105 may be between the first cell contact plugs 152 and the plate layer 101. The cover insulating layer 105 may cover upper ends of the first cell contact plugs 152. The cover insulating layer 105 may not extend to the channel structures CH and the second cell contact plug 154. An upper surface of the cover insulating layer 105 may have a curvature along the upper ends of the first cell contact plugs 152, but the shape of the upper surface of the cover insulating layer 105 is not limited thereto. The cover insulating layer 105 may include an insulating material, for example, at least one of silicon oxide, silicon nitride, or silicon carbide. In some example embodiments, the cover insulating layer 105 may be spaced apart from each other between the first cell contact plugs 152 and may be in a plurality of layers. In some example embodiments, the cover insulating layer 105 may penetrate the plate layer 101.

The cell upper contacts 170 and the cell interconnection lines 180 may form a portion of the second interconnection structure, and may allow the second substrate structure S2 to be electrically connected to the first substrate structure S1.

The cell upper contacts 170 may include first to third cell upper contacts 172, 174, and 176, and the cell interconnection lines 180 may include first and second cell interconnection lines 182 and 184. The channel pads 149 and the first and second cell contact plugs 152 and 154 may be connected to the first cell upper contacts 172 at a lower end. The first cell upper contacts 172 may be connected to the second cell upper contacts 174 at the lower end, and the second cell upper contacts 174 may be connected to the first cell interconnection lines 182 at the lower end. The third cell upper contacts 176 may connect the first and second cell interconnection lines 182 and 184 vertically. The cell upper contacts 170 may have a cylindrical shape. In example embodiments, the cell upper contacts 170 may have an inclined side surface such that a width may decrease toward the plate layer 101 and may increase toward the first substrate structure S1, depending on an aspect ratio.

The first cell interconnection lines 182 may include bitlines connected to channel structures CH and interconnection lines at the same level as a level of the bitlines. The second cell interconnection lines 184 may be interconnection lines below the first cell interconnection lines 182. The cell interconnection lines 180 may have a line shape extending in at least one direction. In example embodiments, the second cell interconnection lines 184 may have a thickness greater than that of the first cell interconnection lines 182. The cell interconnection lines 180 may have an inclined side surface having a width decreasing toward the plate layer 101.

The cell upper contacts 170 and the cell interconnection lines 180 may include, for example, tungsten (W), aluminum (Al), copper (Cu), tungsten nitride (WN), tantalum nitride (TaN), titanium nitride (TiN), or a combination thereof.

The second bonding vias 195 of the second bonding structure may be below the second cell interconnection lines 184 and may be connected to the second cell interconnection lines 184, and the second bonding pads 198 of the second bonding structure may be connected to the second bonding vias 195. The second bonding pads 198 may have lower surfaces exposed to lower surfaces of the second substrate structure S2. The second bonding pads 198 may be bonded and connected to the first bonding pads 298 of the first substrate structure S1, and the second bonding insulating layer 199 may be bonded and connected to the first bonding insulating layer 299 of the first substrate structure S1. The second bonding vias 195 and the second bonding pads 198 may include a conductive material, for example, copper (Cu). The second bonding insulating layer 199 may include at least one of, for example, SiO₂, SiN, SiCN, SiOC, SiON, or SiOCN.

The first and second substrate structures S1 and S2 may be bonded to each other by bonding between the first bonding pads 298 and the second bonding pads 198 and bonding between the first bonding insulating layer 299 and the second bonding insulating layer 199. The bonding between the first bonding pads 298 and the second bonding pads 198 may be, for example, copper (Cu)-copper (Cu) bonding, and the bonding between the first bonding insulating layer 299 and the second bonding insulating layer 199 may be, for example, dielectric-dielectric bonding, such as SiCN—SiCN bonding. The first and second substrate structures S1 and S2 may be bonded to each other by hybrid bonding including copper (Cu)-copper (Cu) bonding and dielectric-dielectric bonding.

The cell region insulating layer 190 may cover a lower surface of the plate layer 101 and the gate electrodes 130 on the lower surface of the plate layer 101. The passivation layer 106 may be on an upper surface of the plate layer 101 and may have openings exposing an input/output pad region IOP. The passivation layer 106 may function as a layer protecting the integrated circuit device 100.

The cell region insulating layer 190 and the passivation layer 106 may include at least one of an insulating material, for example, silicon oxide, silicon nitride, or silicon carbide, and may be formed in a plurality of insulating layers in example embodiments.

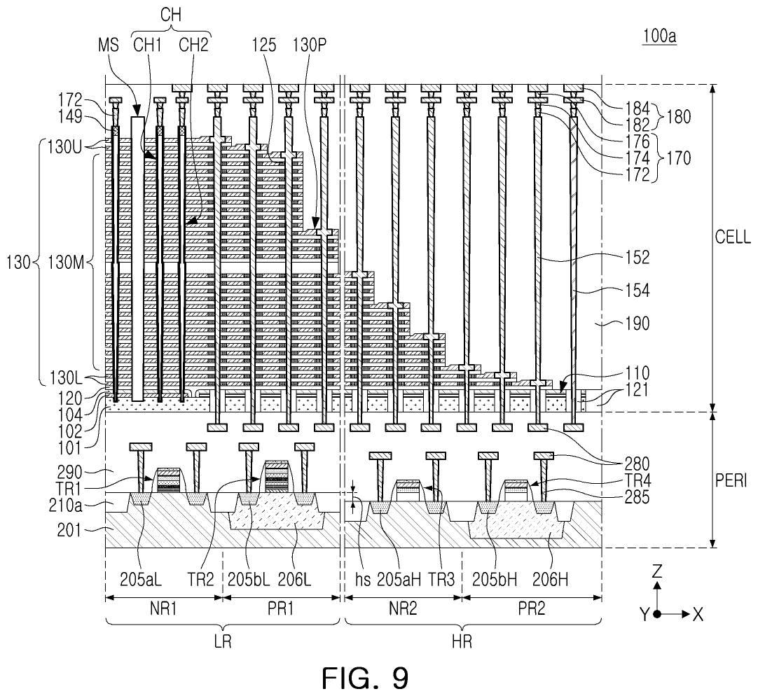

FIG. 9 is a cross-sectional view illustrating an integrated circuit device according to example embodiments.

Referring to FIG. 9, the integrated circuit device 100a may include a peripheral circuit region PERI including a substrate 1 and a memory cell region CELL including a plate layer 101. The memory cell region CELL may be on the peripheral circuit region PERI. In example embodiments, the memory cell region CELL may be below the peripheral circuit region PERI.

The description of the first integrated circuit device structure S1 described above with reference to FIGS. 6 to 8 may be applied to the peripheral circuit region PERI. However, differently from the first integrated circuit device structure S1, the peripheral circuit region PERI may not include the bonding structure, the first bonding vias 295, the first bonding pads 298, and the first bonding insulating layer 299.

As for the memory cell region CELL, unless otherwise indicated, the description of the second integrated circuit device structure S2 described above with reference to FIGS. 6 to 8 may be applied. However, differently from the second integrated circuit device structure S2, the memory cell region CELL may not include the bonding structures, the second bonding vias 195, the second bonding pads 198, and the second bonding insulating layer 199, and may not include the passivation layer 106. The memory cell region CELL may further include first and second horizontal conductive layers 102 and 104 on the plate layer 101, a horizontal insulating structure 110, and a substrate-through insulating layer 121.

The first and second horizontal conductive layers 102 and 104 may be stacked in order on an upper surface of the plate layer 101. The first horizontal conductive layer 102 may function as a portion of a common source line of the integrated circuit device 100f, and may function as a common source line together with the plate layer 101, for example. The first horizontal conductive layer 102 may be directly connected to the channel layer 140 around each of the channel layers 140 of the channel structures CH. The first and second horizontal conductive layers 102 and 104 may include a semiconductor device material, for example, polycrystalline silicon.

The horizontal insulating structure 110 may be on the plate layer 101 in parallel with the first horizontal conductive layer 102. The horizontal insulating structure 110 may include three horizontal insulating layers stacked in order on the plate layer 101. The horizontal insulating structure 110 may be layers remaining after a portion of the integrated circuit device 100a is replaced with the first horizontal conductive layer 102 during a manufacturing process. The horizontal insulating structure 110 may include silicon oxide, silicon nitride, silicon carbide, or silicon oxynitride.

The substrate-through insulating layer 121 may penetrate the plate layer 101, the horizontal insulating structure 110, and the second horizontal conductive layer 104. An upper surface of the substrate-through insulating layer 121 may be coplanar with an upper surface of the second horizontal conductive layer 104, but example embodiments are not limited thereto. The substrate through insulating layer 121 may include an insulating material, for example, silicon oxide, silicon nitride, silicon carbide, or silicon oxynitride.

In example embodiments, the first and second cell contact plugs 152 and 154 may penetrate the gate electrodes 130, may penetrate the substrate-through insulating layer 121 and may be connected to the circuit interconnection lines 280 of the peripheral circuit region PERI.

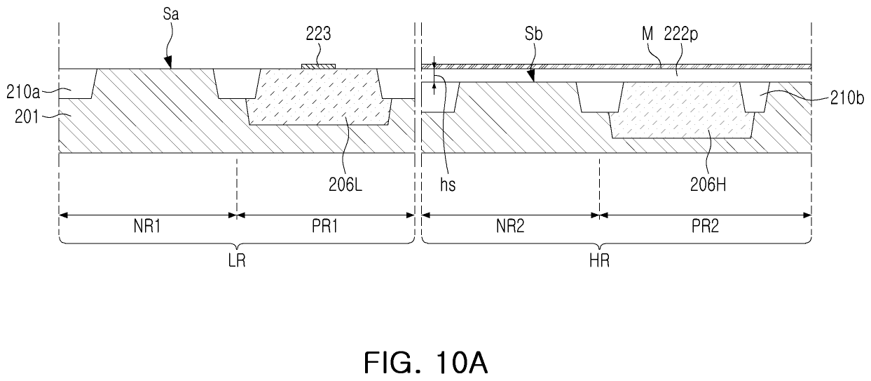

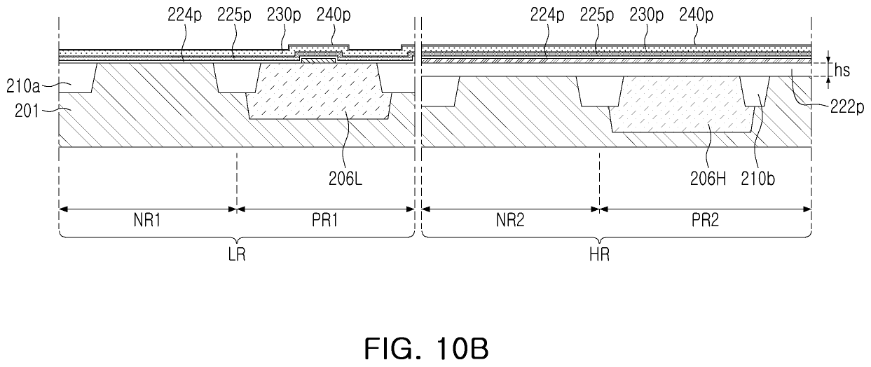

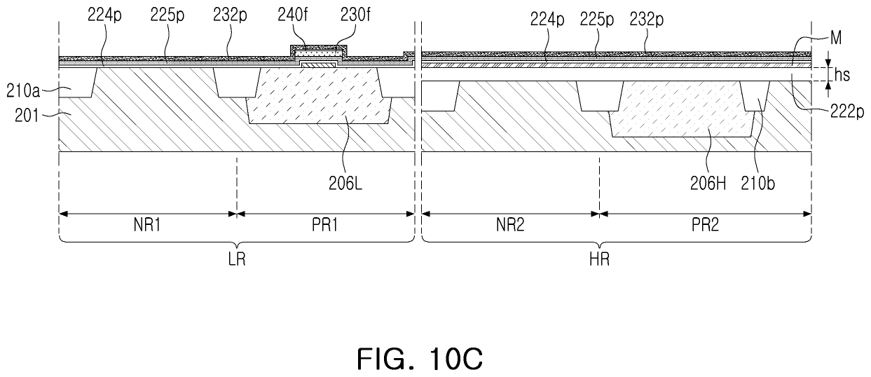

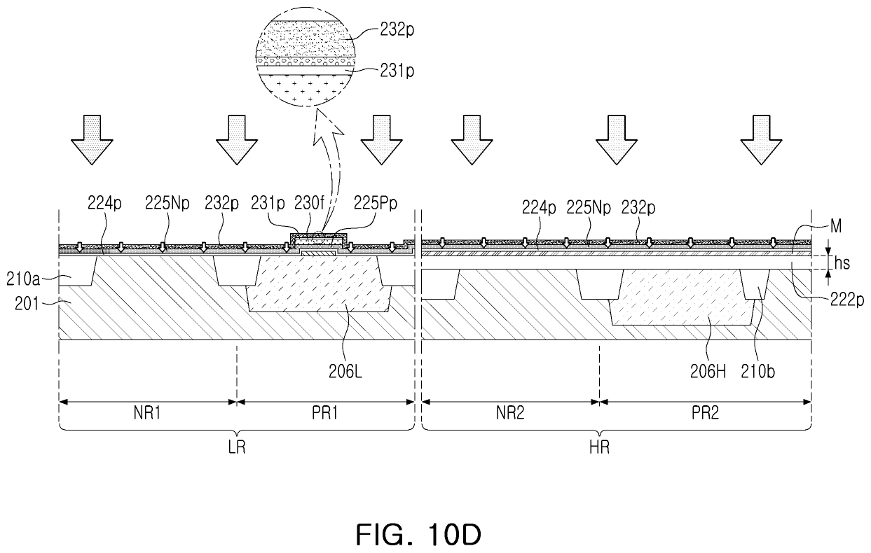

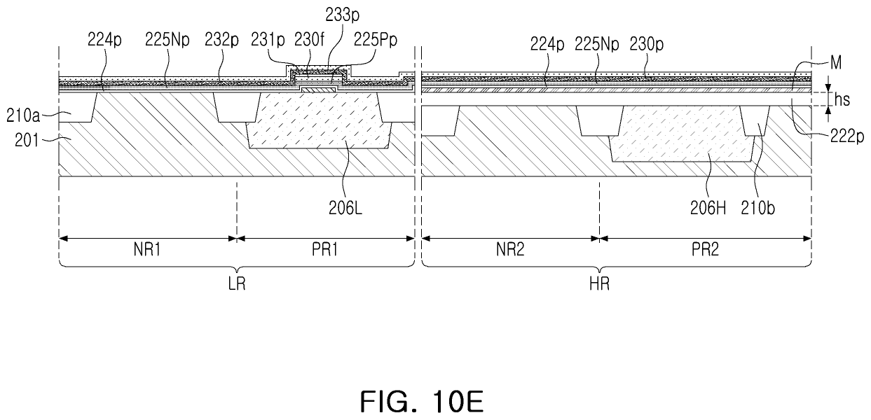

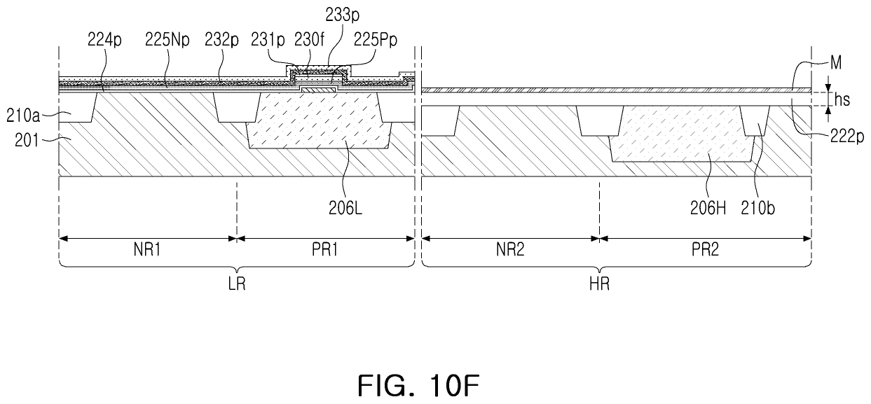

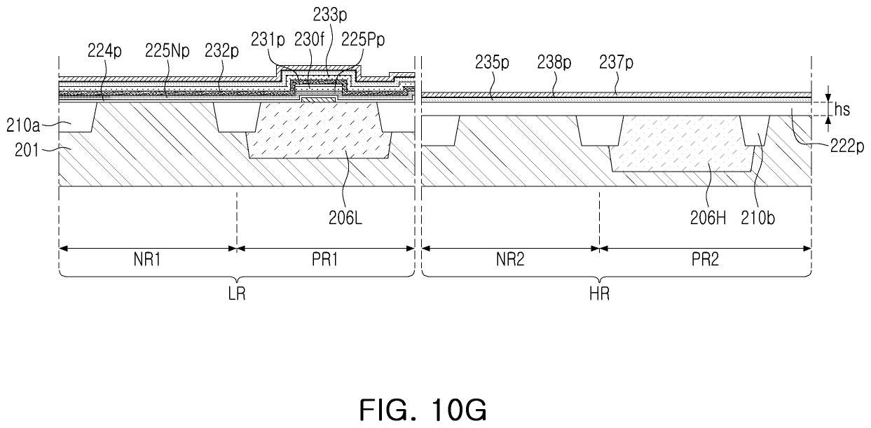

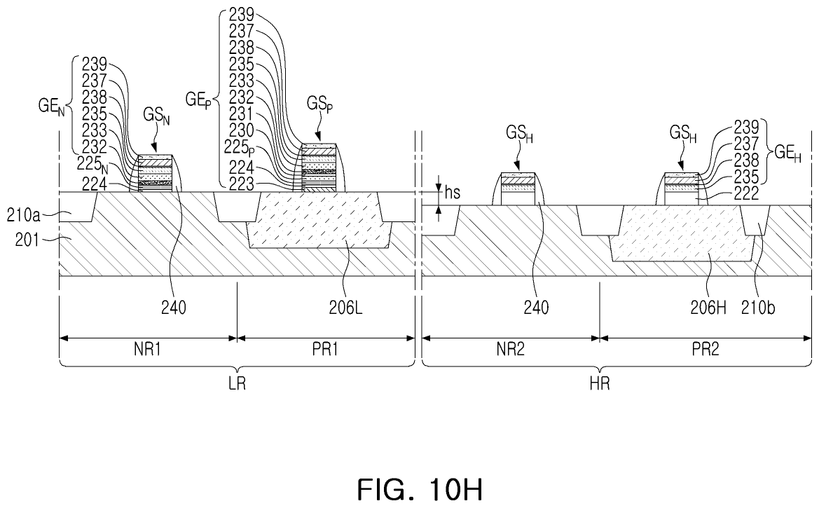

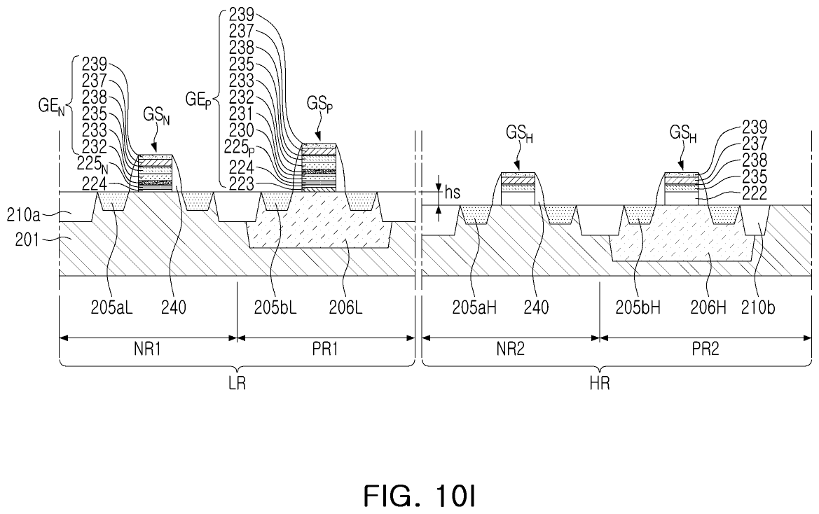

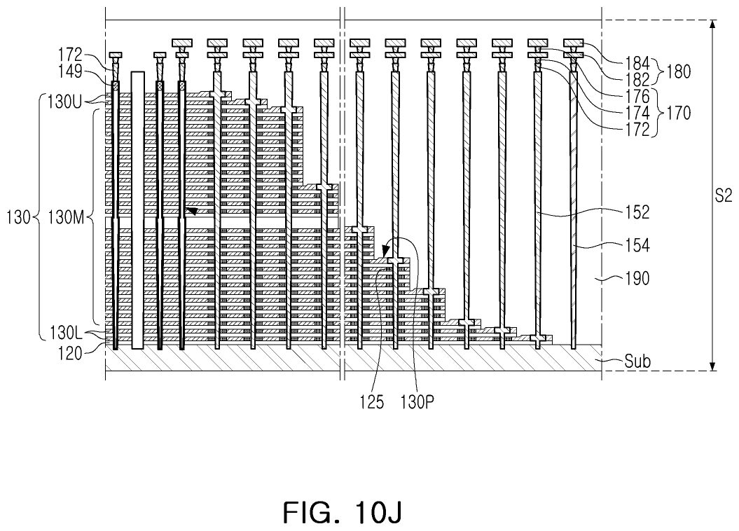

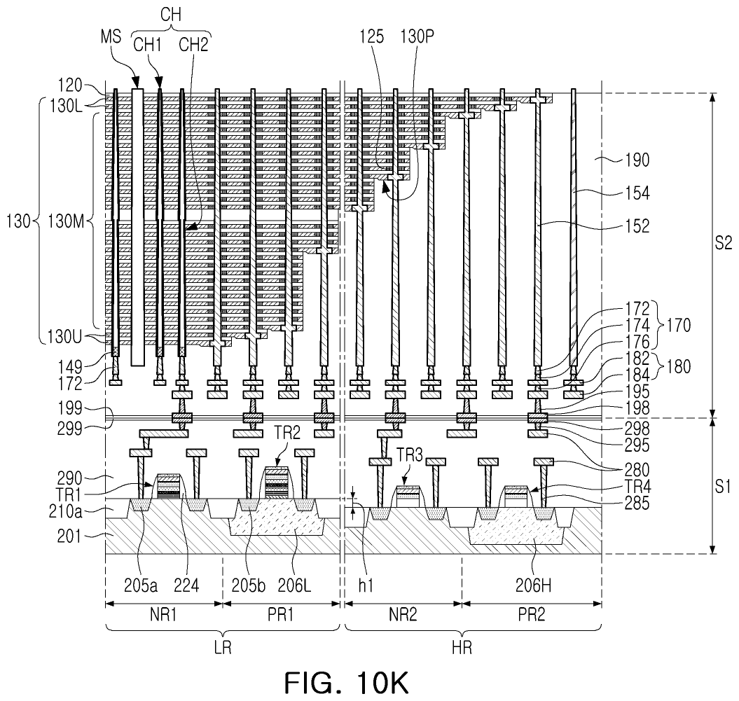

FIGS. 10A, 10B, 10C, 10D, 10E, 10F, 10G, 10H, 10I, 10J, and 10K are cross-sectional views illustrating a method of manufacturing an integrated circuit device according to example embodiments, illustrating regions corresponding to FIG. 6.

Referring to FIG. 10A, a substrate 201 may be prepared.

The substrate 201 may be configured as an integrated circuit device substrate, for example, a silicon wafer. In an upper surface of the substrate 201, a region forming a high-voltage device region HR and a low-voltage device region LR may be divided, and an upper surface of the high-voltage device region HR may be etched to have a substrate step difference hs from an upper surface of the low-voltage device region LR.

Accordingly, the substrate 201 may have a first upper surface Sa in the low-voltage device region LR, and may have a second upper surface Sb at a level lower than a level of the substrate step difference hs in the high-voltage device region HR.

By doping impurities in the second device region PR1 and the fourth device region PR2 in which PMOS transistors of the high-voltage device region HR and the low-voltage device region LR are located, first and second well regions 206L and 206H may be formed, and device isolation regions 210a and 210b may be formed, respectively. The device isolation regions 210a and 210b may be formed by forming shallow trenches and stacking oxide, but example embodiments are not limited thereto.

The preliminary gate dielectric layer 222p may be formed on the substrate 201 of the high-voltage device region HR with a thickness T7 the same as the substrate step difference hs. The preliminary gate dielectric layer 222p may be formed having a large thickness using a material having a low dielectric constant, such as silicon oxide or silicon oxynitride.

An etching mask layer M may be further formed on the preliminary gate dielectric layer 222p. The etching mask layer M may be formed to have a relatively small thickness of polysilicon using polysilicon, and may be selectively formed only in the high-voltage device region HR.

A channel structure 223 may be further formed in an area in which a gate structure GS_{P} is formed on the substrate 201 of the second device region PR1 in the low-voltage device region LR. The channel structure 223 may include a semiconductor device material having a band gap smaller than that of the substrate 201 material, and may include silicon-germanium.

Referring to FIG. 10B, a preliminary interfacial insulating layer 224p, a preliminary gate dielectric layer 225p, a preliminary lower conductive layer 230P, and an impurity treatment layer 240P may be formed in order throughout the low-voltage device region LR and the high-voltage device region HR.

The preliminary interfacial insulating layer 224p may be formed by stacking materials forming the first and second interfacial insulating layers 224 entirely on the first and second upper surfaces Sa and Sb of the substrate 201, and may be formed by depositing silicon oxide to have a first thickness T1. The preliminary gate dielectric layer 225p may include a high-k material, may be deposited to have a second thickness T2, and may be formed by depositing hafnium oxide (HfO) on the preliminary interfacial insulating layer 224p, but example embodiments are not limited thereto. The preliminary gate dielectric layer 225p may be formed by depositing metal oxide or metal nitride not including other impurities.

The preliminary lower conductive layer 230P may include metal nitride, and may be formed by depositing titanium nitride by a fifth thickness T5.

The impurity treatment layer 240P may be a material layer including impurities to be included in the preliminary lower conductive layer 230P, and may be deposited with silicon, carbon, or germanium by a thickness less than the first thickness T1, for example, 10 Å or lower. By depositing SiH₄ or Si₂H₆ at 350-450 degrees, the impurity treatment layer 240P including silicon may be deposited with a thickness of 10 Å or lower.

Referring to FIG. 10C, the preliminary lower conductive layer 230P and the impurity treatment layer 240P may be etched and patterned to remain only within the area of the gate structure GS_{P} in the second circuit region PR1. In this case, the patterned preliminary lower conductive pattern 230f and the patterned impurity treatment pattern 240f may vertically overlap the channel structure 223 therebelow, and may be to cover the entire channel structure.

The preliminary work function tuning layer 232p may be formed to cover the patterned preliminary lower conductive pattern 230f and the impurity treatment pattern 240f, and to cover both the low-voltage device region LR and the high-voltage device region HR.

The preliminary work function tuning layer 232p may include an oxide or nitride including a high reactivity metal material, and may deposit lanthanum oxide (La₂O₃) including lanthanum. The preliminary work function tuning layer 232p may be conformally formed along the shape of the preliminary lower conductive pattern 230f and the impurity treatment pattern 240f. In the case of including lanthanum, the preliminary work function tuning layer 232p may not perform a patterning or etching process, such that damages due to high reactivity of lanthanum may be prevented.

Referring to FIG. 10D, annealing may be performed while the preliminary work function tuning layer 232p is formed on the uppermost surface, such that lanthanum, which is a high reactivity metal material in the preliminary work function tuning layer 232p, may be diffused downwardly.

In this case, the annealing may be performed at a temperature of 800 degrees or higher, and by the high-temperature heat treatment, impurities of the impurity treatment pattern 240f may diffuse into the preliminary lower conductive pattern 230f below, such that the crystal structure of the upper portion of the preliminary lower conductive pattern 230f may be changed, thereby forming the preliminary diffusion barrier 231p.

The preliminary diffusion barrier 231p may form a Ti—Si—N structure as silicon (Si) atoms of the impurity treatment pattern 240f diffuse into titanium nitride of the preliminary lower conductive pattern 230f, which may have an amorphous structure. Accordingly, since the structure is denser than the polycrystalline structure of the titanium nitride (TiN) of the previous preliminary lower conductive pattern 230f, lanthanum from the preliminary work function tuning layer 232p in an upper portion may be blocked from diffusing into the preliminary lower conductive pattern 230f therebelow. Silicon in the preliminary diffusion barrier 231p may satisfy 2% or more.

Accordingly, the preliminary gate dielectric layer 225p in the region in which the preliminary diffusion barrier 231p is formed may include materials such as the second gate dielectric layer 255p not containing lanthanum, and in the preliminary gate dielectric layer 225Np in the region in which the preliminary diffusion barrier 231p is not formed, lanthanum may be diffused from the preliminary work function tuning layer 232p in the upper portion and may include the same material as the first gate dielectric layer 255N. Accordingly, the same preliminary gate dielectric layer 225p may include different materials depending on the regions.

Lanthanum in the preliminary work function tuning layer 232p on the preliminary diffusion barrier 231p may not diffuse downwardly and may remain, such that the preliminary work function tuning layer 232p on the preliminary diffusion barrier 231p may have a second concentration of lanthanum greater than the first concentration of lanthanum in other regions.

A portion of silicon, which is one of impurities, may be diffused into the lower surface of the preliminary work function tuning layer 232p on the preliminary diffusion barrier 231p and may form the lower work function tuning layer 232i, and a thickness of the lower work function tuning layer 232i may be smaller than a thickness of the preliminary diffusion barrier 231p.

Thereafter, referring to FIG. 10E, the preliminary first conductive layer 233p may be formed entirely on the entire low-voltage device region LR and the high-voltage device region HR. The preliminary first conductive layer 233p may include the same material as a material of the preliminary lower conductive pattern 230f and may be formed conformally.

As illustrated in FIG. 10F, by etching the stacked material layers of the high-voltage device region HR, the etching mask layer M may be exposed.

That is, the material layers stacked only in the low-voltage device region LR may remain, and the preliminary interfacial insulating layer 224p to the preliminary first conductive layer 233p stacked on the etching mask layer M in the high-voltage device region HR may be removed entirely.

Referring to FIG. 10G, a preliminary second conductive layer 235p, a preliminary ohmic contact layer 238p, and a preliminary third conductive layer 237p may be stacked in order throughout the low-voltage device region LR and the high-voltage device region HR.

The preliminary second conductive layer 235p may include polysilicon, and may be formed without a boundary with the etching mask layer M by including the same material as that of the etching mask layer M.

The preliminary ohmic contact layer 238p may be formed using a material such as tantalum nitride or titanium nitride by a relatively small thickness. The preliminary third conductive layer 237p may be formed on the preliminary ohmic contact layer 238p. The preliminary third conductive layer 237p may include a metal material such as tungsten or aluminum.

Referring to FIG. 10H, a mask layer 239 may be formed in the region exhibiting the gate structures GS_{N}, GS_{P}, and GS_{H} of the first, second, third, and fourth circuit devices TR1, TR2, TR3, and TR4, and may be etched, thereby forming the gate structures GS_{N}, GS_{P}, and GS_{H}.

The mask layer 239 may be silicon nitride, silicon oxynitride, or the like, and may be patterned as a mask, thereby forming the gate structures GS_{N}, GS_{P}, and GS_{H} defining the circuit devices TR1-TR4.

As for heights of the gate structures GS_{N}, GS_{P}, and GS_{H}, the second circuit device TR2 may be the highest, and the third and fourth circuit devices TR3 and TR4 may be the lowest.

Referring to FIG. 10I, gate spacers 240 may be formed on both (i.e. opposite) sidewalls of the gate structures GS_{N}, GS_{P}, and GS_{H} of the circuit devices TR1, TR2, TR3, and TR4, thereby forming first, second, third, and fourth gate structures GS_{N}, GS_{P}, and GS_{H}. Thereafter, by performing an ion implantation process, source/drain regions 205aL, 205bL, 205aH and 205bH may be formed in the substrate 201 on both (i.e. opposite) sides of each of the gate structures GS_{N}, GS_{P}, and GS_{H}. Accordingly, the first, second, third, and fourth circuit devices TR1, TR2, TR3, TR4 may be manufactured.

Thereafter, contact plugs 285 may be formed by forming a portion of a peripheral region insulating layer 290, removing a portion thereof by etching, and filling a conductive material. Circuit interconnection lines 280 may be formed, for example, by depositing a conductive material and patterning the material.

Thereafter, the first bonding insulating layer 299 may be formed on the circuit interconnection lines 280. The first bonding vias 295 and the first bonding pads 298 of the first bonding structure may be formed after partially removing the first bonding insulating layer 299 and the peripheral region insulating layer 290.

By this process, the first substrate structure S1 may be prepared.

Thereafter, referring to FIG. 10J, a second substrate structure S2 may be manufactured.

In the second substrate structure S2, sacrificial insulating layers and interlayer insulating layers 120 may be alternately stacked on a base substrate Sub.

The base substrate Sub may be removed through a subsequent process and may be configured as an integrated circuit device substrate such as undoped silicon (Si). The sacrificial insulating layers may be replaced with gate electrodes 130 (see FIG. 6) through a subsequent process. The sacrificial insulating layers may be formed of a material etched with etch selectivity with respect to the interlayer insulating layers 120. For example, the interlayer insulating layer 120 may be formed of at least one of silicon oxide or silicon nitride, and the sacrificial insulating layers may be formed of a material different from that of the interlayer insulating layer 120 selected from among silicon, silicon oxide, silicon carbide, and silicon nitride. In example embodiments, a thickness of the interlayer insulating layers 120 and the number of films included in the layers may be varied from the illustrated example.

Thereafter, in regions including ends of the sacrificial insulating layers, a staircase shape may be formed by repeating the photolithography process and the etching process. The sacrificial insulating layers may be formed having a large thickness at the ends, and processes therefor may be further performed. A portion of the cell region insulating layer 190 covering the lower stack structure of the sacrificial insulating layers and the interlayer insulating layers 120 may be formed.

Vertical sacrificial layers may be formed to correspond to each channel structure, and the vertical sacrificial layers may include, for example, polycrystalline silicon.

Channel structures CH penetrating the stack structure of the sacrificial insulating layers and the interlayer insulating layers 120 may be formed.

Channel holes may be formed by removing the vertical sacrificial layers. Thereafter, a gate dielectric layer 145, a channel layer 140, a channel filling insulating layer 147, and a channel pad 149 may be formed in order in each of the channel holes and channel structures CH including first and second channel structures CH1 and CH2 may be formed. The channel layer 140 may be formed on the gate dielectric layer 145 in the channel structures CH. The channel filling insulating layer 147 may be formed to fill the channel structures CH and may be an insulating material. However, in example embodiments, a space between the channel layers 140 may be filled with a conductive material other than the channel filling insulating layer 147. The channel pads 149 may be formed of a conductive material, for example, may be formed of polycrystalline silicon.

Thereafter, an opening penetrating sacrificial insulating layers and interlayer insulating layers 120 and extending to the plate layer 101 may be formed in a region corresponding to the isolation region MS, and the sacrificial insulating layers may be removed by supplying an etchant through the opening. The sacrificial insulating layers may be selectively removed, for example, using wet etching, with respect to the interlayer insulating layers 120.

The gate electrodes 130 may be formed by depositing a conductive material in the regions from which the sacrificial insulating layers are removed. The conductive material may include a metal, polycrystalline silicon, or a metal silicide material. After the gate electrodes 130 are formed, an isolation region MS may be formed by depositing an insulating material in the opening.

Thereafter, the first cell contact plugs 152 may be formed by depositing a conductive material in the contact holes. When the contact sacrificial layers previously formed in the regions in which the contact holes are formed are removed, the insulating material may also be partially removed. In this case, the insulating material may be entirely removed from the pad regions 130P, and the insulating material may remain therebelow and may form the contact insulating layers 125. The first cell contact plugs 152 may be formed to have regions extending horizontally from the pad regions 130P, and may thus be physically and electrically connected to the gate electrodes 130. The second cell contact plugs 154 may be formed by forming contact holes extending into the base substrate Sub by penetrating the cell region insulating layer 190 on an outer side of the gate electrodes 130, and depositing a conductive material into the contact holes. The process of depositing the conductive material may be performed simultaneously with the deposition process for the first cell contact plugs 152, but example embodiments are not limited thereto.

A second interconnection structure and a second bonding structure may be formed on the gate electrodes 130. In the second interconnection structure, the cell upper contacts 170 may be formed by etching the cell region insulating layer 190 and depositing a conductive material on the channel pads 149 and the first and second cell contact plugs 152 and 154. The cell interconnection lines 180 may be formed through a process of depositing and patterning a conductive material, or by forming a portion of a cell region insulating layer 190, patterning the layer and depositing a conductive material.

In the second bonding structure, the second bonding insulating layer 199 may be formed on the cell region insulating layer 190. Thereafter, second bonding vias 195 may be formed by partially removing the second bonding insulating layer 199 and the cell region insulating layer 190 and depositing a conductive material, and second bonding pads 198 may be formed on the second bonding vias 195. In some example embodiments, the second bonding vias 195 and the second bonding pads 198 may be vertically integrated (e.g. connected) with each other. Upper surfaces of the second bonding pads 198 may be exposed from the cell region insulating layer 190.

Referring to FIG. 10K, the first substrate structure S1 and the second substrate structure S2 may be connected to each other by bonding the first bonding pads 298 and the second bonding pads 198 by annealing and/or applying pressure. Simultaneously, the first bonding insulating layer 299 and the second bonding insulating layer 199 may also be bonded to each other. The second substrate structure S2 may be upside down on the first substrate structure S1 such that the second bonding pads 198 may be directed downwardly, and bonding may be performed. The first substrate structure S1 and the second substrate structure S2 may be directly bonded to each other without using an adhesive such as an adhesive layer therebetween.

The base substrate Sub may be removed from the bonding structure of the first and second substrate structures S1 and S2.

For example, the base substrate Sub may be partially removed from the upper surface by a polishing process such as a grinding process, and the other portion may be removed by an etching process such as wet etching. By removing the base substrate Sub of the second substrate structure S2, the total thickness of the integrated circuit device may be reduced. By removing the base substrate Sub, upper ends of the channel structures CH and the first and second cell contact plugs 152 and 154 may be exposed. The channel dielectric layers 145 (see FIG. 8) may be partially removed from upper ends of the exposed channel structures CH.

Thereafter, as illustrated in FIG. 6, a plate layer 101 may be formed on upper ends of the channel structures CH, and an insulating material may be deposited on the exposed upper ends of the first cell contact plugs 152, thereby forming a cover insulating layer 105.

The plate layer 101 may be formed by depositing a semiconductor device material. The plate layer 101 may be formed, for example, by depositing amorphous silicon (Si) and crystallizing the material. A passivation layer 106 may be formed on the plate layer 101.

Accordingly, the integrated circuit device 100 in FIG. 6 may be manufactured.

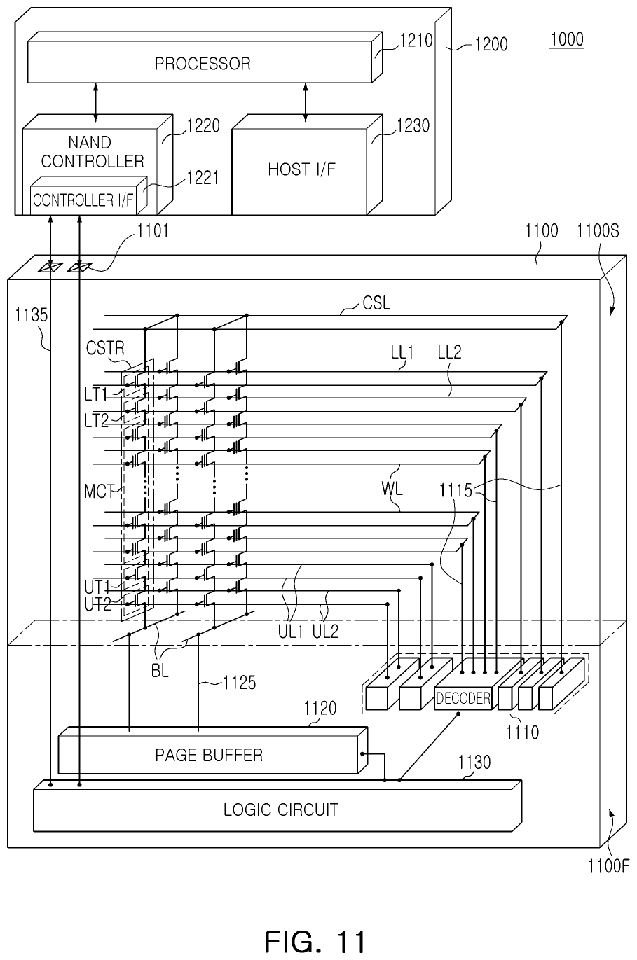

FIG. 11 is a perspective view illustrating a data storage system including an integrated circuit device according to example embodiments.

Referring to FIG. 11, a data storage system 1000 may include an integrated circuit device 1100 and a controller 1200 electrically connected to the integrated circuit device 1100. The data storage system 1000 may be implemented as a storage device including one or a plurality of integrated circuit devices 1100 or an electronic device including a storage device. For example, the data storage system 1000 may be implemented as a solid state drive device (SSD) including one or a plurality of integrated circuit devices 1100, a universal serial bus (USB), a computing system, a medical device, or a communication device.

The integrated circuit device 1100 may be implemented as a non-volatile memory device, such as, for example, the NAND flash memory device described in the aforementioned example embodiments with reference to FIGS. 6 to 9. The integrated circuit device 1100 may include a first structure 1100F and a second structure 1100S on the first structure 1100F. In example embodiments, the first structure 1100F may be on the side of the second structure 1100S. The first structure 1100F may be a peripheral circuit structure including a decoder circuit 1110, a page buffer 1120, and a logic circuit 1130. The second structure 1100S may be implemented as a memory cell structure including a bitline BL, a common source line CSL, wordlines WL, first and second gate upper lines UL1 and UL2, first and second gate lower lines LL1 and LL2 and memory cell strings CSTR between the bitline BL and the common source line CSL.

In the second structure 1100S, each of the memory cell strings CSTR may include lower transistors LT1 and LT2 adjacent to the common source line CSL, upper transistors UT1 and UT2 adjacent to the bitline BL, and a plurality of memory cell transistors MCT between the lower transistors LT1 and LT2 and the upper transistors UT1 and UT2. The number of lower transistors LT1 and LT2 and the number of upper transistors UT1 and UT2 may be varied in example embodiments.

In example embodiments, the upper transistors UT1 and UT2 may include a string select transistor, and the lower transistors LT1 and LT2 may include a ground select transistor. The gate lower lines LL1 and LL2 may be configured as gate electrodes of the lower transistors LT1 and LT2, respectively. The wordlines WL may be configured as gate electrodes of the memory cell transistors MCT, and the gate upper lines UL1 and UL2 may be configured as gate electrodes of the upper transistors UT1 and UT2, respectively.

In example embodiments, the lower transistors LT1 and LT2 may include a lower erase control transistor LT1 and a ground select transistor LT2 connected to each other in series. The upper transistors UT1 and UT2 may include a string select transistor UT1 and an upper erase control transistor UT2 connected to each other in series. At least one of the lower erase control transistor LT1 and the upper erase control transistor UT2 may be used in an erase operation for erasing data stored in the memory cell transistors MCT using a GIDL phenomenon.

The common source line CSL, the first and second gate lower lines LL1 and LL2, the wordlines WL, and the first and second gate upper lines UL1 and UL2 may be electrically connected to the decoder circuit 1110 through first connection interconnections 1115 extending from the first structure 1100F to the second structure 1100S. The bitlines BL may be electrically connected to the page buffer 1120 through second connection interconnections 1125 extending from the first structure 110F to the second structure 1100S.

In the first structure 1100F, the decoder circuit 1110 and the page buffer 1120 may perform a control operation on at least one selected memory cell transistor among the plurality of memory cell transistors MCT. The decoder circuit 1110 and the page buffer 1120 may be configured to be controlled by the logic circuit 1130. The integrated circuit device 1100 may communicate with the controller 1200 through the input/output pad 1101 electrically connected to the logic circuit 1130. The input/output pads 1101 may be electrically connected to the logic circuit 1130 through an input/output connection line 1135 extending from the first structure 1100F to the second structure 1100S.

The controller 1200 may include a processor 1210, a NAND controller 1220, and a host interface 1230. In example embodiments, the data storage system 1000 may include a plurality of integrated circuit devices 1100, and in this case, the controller 1200 may be configured to control the plurality of integrated circuit devices 1100.

The processor 1210 may be configured to control overall operation of the data storage system 1000 including the controller 1200. The processor 1210 may operate according to a predetermined firmware, and may access the integrated circuit device 1100 by being configured to control the NAND controller 1220. The NAND controller 1220 may include a controller interface 1221 processing communication with the integrated circuit device 1100. Through the controller interface 1221, a control command configured to control the integrated circuit device 1100, data to be written to the memory cell transistors MCT of the integrated circuit device 1100, and data to be read from the memory cell transistors MCT of the integrated circuit device 1100 may be transmitted. The host interface 1230 may provide a communication function between the data storage system 1000 and an external host. When a control command from an external host is received through the host interface 1230, the processor 1210 may be configured to control the integrated circuit device 1100 in response to the control command.

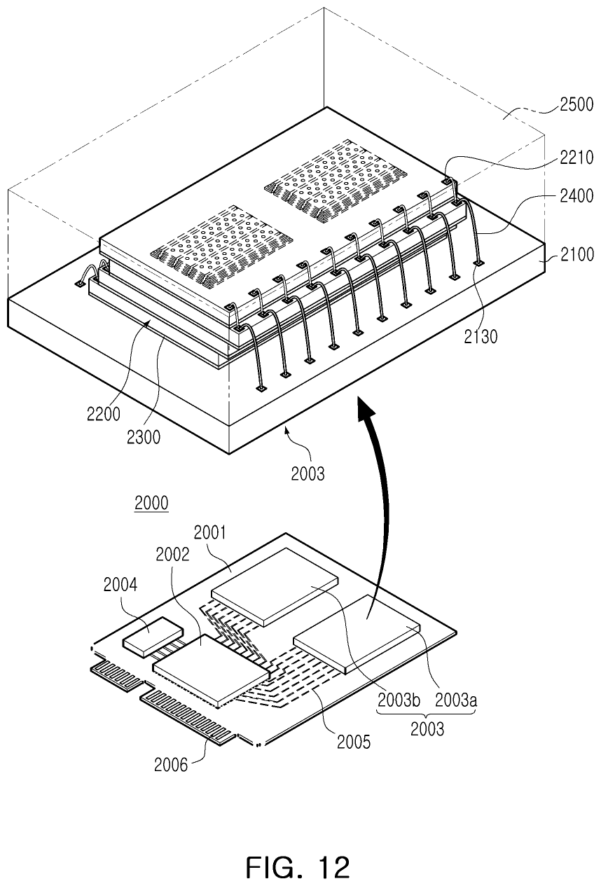

FIG. 12 is a perspective view illustrating a data storage system including an integrated circuit device according to example embodiments.

Referring to FIG. 12 a data storage system 2000 in example embodiments may include a main board 2001, a controller 2002 mounted on the main board 2001, one or more semiconductor packages 2003, and a DRAM 2004. The semiconductor package 2003 and the DRAM 2004 may be connected to the controller 2002 by interconnection patterns 2005 formed on the main board 2001.

The main board 2001 may include a connector 2006 including a plurality of pins coupled to an external host. The number and arrangement of the plurality of pins in the connector 2006 may vary depending on a communication interface between the data storage system 2000 and the external host. In example embodiments, the data storage system 2000 may communicate with an external host according to one of interfaces from among universal serial bus (USB), peripheral component interconnect express (PCI-Express), serial advanced technology attachment (SATA), M-Phy for universal flash storage (UFS). In example embodiments, the data storage system 2000 may operate by power supplied from an external host through the connector 2006. The data storage system 2000 may further include a power management integrated circuit (PMIC) for distributing power supplied from the external host to the controller 2002 and the semiconductor package 2003.

The controller 2002 may write data to or may read data from the semiconductor package 2003, and may improve an operating speed of the data storage system 2000.

The DRAM 2004 may be configured as a buffer memory for alleviating a difference in speeds between the semiconductor package 2003, which is a data storage space, and an external host. The DRAM 2004 included in the data storage system 2000 may operate as a cache memory, and may provide a space for temporarily storing data in a control operation for the semiconductor package 2003. When the data storage system 2000 may include the DRAM 2004, the controller 2002 may further include a DRAM controller configured to control the DRAM 2004 in addition to the NAND controller configured to control the semiconductor package 2003.

The semiconductor package 2003 may include first and second semiconductor packages 2003a and 2003b spaced apart from each other. Each of the first and second semiconductor packages 2003a and 2003b may be configured as a semiconductor package including a plurality of semiconductor chips 2200. Each of the first and second semiconductor packages 2003a and 2003b may include a package substrate 2100, semiconductor chips 2200 on the package substrate 2100, adhesive layers 2300 on lower surfaces of the semiconductor chips 2200, respectively, a connection structure 2400 electrically connecting the semiconductor chips 2200 to the package substrate 2100, and a molding layer 2500 covering the semiconductor chips 2200 and the connection structure 2400 on the package substrate 2100.

The package substrate 2100 may be configured as a printed circuit board including upper pads 2130. Each semiconductor chip 2200 may include an input/output pad 2210. The input/output pad 2210 may correspond to the input/output pad 1101 in FIG. 11. Each of the semiconductor chips 2200 may include gate stack structures 3210 and channel structures 3220. Each of the semiconductor chips 2200 may include the integrated circuit device described in the aforementioned example embodiments with reference to FIGS. 6 to 9.

In example embodiments, the connection structure 2400 may be configured as a bonding wire electrically connecting the input/output pad 2210 to the upper package pads 2130. Accordingly, in each of the first and second semiconductor packages 2003a and 2003b, the semiconductor chips 2200 may be electrically connected to each other by a bonding wire method, and may be electrically connected to the upper pads 2130 of the package substrate 2100. In example embodiments, in each of the first and second semiconductor packages 2003a and 2003b, the semiconductor chips 2200 may be electrically connected to each other by a connection structure including a through-electrode (TSV) instead of the connection structure 2400 of a bonding wire method.

In example embodiments, the controller 2002 and the semiconductor chips 2200 may be included in a single package. In example embodiments, the controller 2002 and the semiconductor chips 2200 may be mounted on an interposer substrate different from the main board 2001, and the controller 2002 and the semiconductor chips 2200 may be connected to each other by interconnection formed on the interposer substrate.

According to the aforementioned example embodiments, by including a work function tuning layer in the gate structures of NMOS transistors and PMOS transistors of low-voltage transistors including a high-k gate dielectric layer, each of the work functions may be adjusted, and the difference in levels of transistors may be reduced.

Accordingly, as the NMOS transistor and PMOS transistor include a work function tuning layer, and a diffusion barrier is formed in the lower portion of the work function tuning layer in the PMOS transistor, diffusion of high reactivity metal from the work function tuning layer may be prevented, such that gate structures having different work functions may be formed, and the thickness of the conductive layer in the lower portion may be reduced.

While example embodiments of the present disclosure have been illustrated and described above with reference to the accompanying drawings, it will be understood that those skilled in the art may make modifications and variations in form or detail without departing from the scope of the following claims. Therefore, the example embodiments described above should be considered as illustrative and non-limiting in all respects.

What is claimed is:

1. An integrated circuit device, comprising:
a substrate;
a first conductivity-type circuit device extending at least partially within the substrate and comprising:
a first gate structure including a first interfacial insulating layer on the substrate; a first gate dielectric layer on the first interfacial insulating layer; a first work function tuning layer on the first gate dielectric layer; and at least one first gate conductive layer on the first work function tuning layer; and
first source/drain regions of first conductivity type extending within the substrate and on opposite sides of the first gate structure, and
a second conductivity-type circuit device extending at least partially within the substrate and comprising:
a second gate structure including a second interfacial insulating layer on the substrate; a second gate dielectric layer on the second interfacial insulating layer; a diffusion barrier layer on the second gate dielectric layer; a second work function tuning layer on the diffusion barrier layer; and at least one second gate conductive layer on the second work function tuning layer; and
second source/drain regions of second conductivity type, extending within the substrate and on opposite sides of the second gate structure.

2. The integrated circuit device of claim 1, wherein each of the first and second work function tuning layers includes an oxide or oxynitride of a high reactivity metal selected from a group consisting of at least one scandium (Sc), yttrium (Y), actinium (Ac), lanthanum (La), strontium (Sr), and/or hafnium.

3. The integrated circuit device of claim 2, wherein a concentration of high reactivity metal within the second work function tuning layer is greater than a concentration of high reactivity metal within the first work function tuning layer.

4. The integrated circuit device of claim 2, wherein the high reactivity metal within the first work function tuning layer is different than the high reactivity metal within the second work function tuning layer.

5. The integrated circuit device of claim 4, wherein the first gate dielectric layer includes a high reactivity metal and are in direct contact with the first work function tuning layer.

6. The integrated circuit device of claim 4, wherein a first high reactivity metal of the first gate dielectric layer is different from a second high reactivity metal of the second gate dielectric layer.

7. The integrated circuit device of claim 6, wherein the first gate dielectric layer includes the first high reactivity metal, and the second gate dielectric layer does not include the first or second high reactivity metal.

8. The integrated circuit device of claim 1, wherein an interfacial surface between the diffusion barrier layer and the second work function tuning layer has an amorphous structure.

9. The integrated circuit device of claim 1, wherein the diffusion barrier layer includes a first metal nitride with silicon.

10. The integrated circuit device of claim 9, wherein a concentration of silicon in the diffusion barrier layer is 2% or more.

11. The integrated circuit device of claim 9, wherein a concentration of silicon decreases from an upper surface of the diffusion barrier layer to a lower surface of the diffusion barrier layer.

12. The integrated circuit device of claim 9, wherein each second conductivity-type circuit device includes a lower conductive layer between the diffusion barrier layer and the second gate dielectric layer, and
wherein the lower conductive layer includes a second metal nitride that is the same as the first metal nitride of the diffusion barrier layer.

13. The integrated circuit device of claim 12, wherein a first thickness of the lower conductive layer is greater than a second thickness of the diffusion barrier layer.

14. The integrated circuit device of claim 1, wherein a first height of the first gate structure of the first conductivity-type circuit device is smaller than a second height of the second gate structure of the second conductivity-type circuit device.

15. An integrated circuit device, comprising:
a memory cell structure including a plurality of gate electrodes, a plurality of channel structures extending through the plurality of gate electrodes, and a plurality of contact plugs electrically connected to the plurality of gate electrodes; and
a first structure electrically connected to the memory cell structure wherein the first structure includes a substrate, a low-voltage device region and a high-voltage region,
wherein the low-voltage device region comprises a plurality of first circuit devices of a plurality of first conductivity-type circuit devices and a plurality of second circuit devices of a plurality of second conductivity-type circuit devices,
wherein the high-voltage device region comprises a plurality of third circuit devices of the plurality of first conductivity-type circuit devices and a plurality of fourth circuit devices of the plurality of second conductivity-type circuit devices,
wherein each of the plurality of first circuit devices includes a first gate structure including a first interfacial insulating layer on the substrate; a first gate dielectric layer on the first interfacial insulating layer; a first work function tuning layer on the first gate dielectric layer; and a plurality of first gate conductive layers on the first work function tuning layer,
wherein each of the plurality of second circuit devices includes a second gate structure including a second interfacial insulating layer on the substrate; a second gate dielectric layer on the second interfacial insulating layer; a diffusion barrier on the second gate dielectric layer; a second work function tuning layer on the diffusion barrier; and a plurality of second gate conductive layers on the second work function tuning layer,
wherein each of the plurality of third circuit devices includes a third gate structure including a third gate dielectric layer having a first thickness that is greater than a second thickness of the first gate dielectric layer and a third thickness of the second gate dielectric layer on the substrate; and a plurality of third gate conductive layers on the third gate dielectric layer,
wherein each of the plurality of fourth circuit devices includes a fourth gate structure including the third gate dielectric layer on the substrate; and the plurality of third gate conductive layers on the third gate dielectric layer, and
wherein the first work function tuning layer and the second work function tuning layer include a high reactivity metal, and a first concentration of the high reactivity metal in the first work function tuning layer is less than a second concentration of the high reactivity metal in the second work function tuning layer.

16. The integrated circuit device of claim 15, wherein a first stack structure of the first gate structure and a second stack structure of the second gate structure are different,
wherein a third stack structure of the third gate structure and a fourth stack structure of the fourth gate structure are the same, and
wherein the third stack structure and the fourth stack structure are both different from the first and second stack structures of the first and second gate structures.

17. The integrated circuit device of claim 15, wherein the substrate includes a first upper surface in the low-voltage device region and a second upper surface in the high-voltage device region, and
wherein the second upper surface is lower than the first upper surface in a vertical direction.

18. The integrated circuit device of claim 15, wherein a third height of the third gate structure and a fourth height of the fourth gate structure are lower than a second height of the second gate structure in a vertical direction.

19. The integrated circuit device of claim 15, wherein the diffusion barrier includes silicon titanium nitride with a concentration of silicon at 2% or more.

20. A data storage system, comprising:
an integrated circuit device including:
a first substrate structure including a substrate, a plurality of first conductivity-type circuit devices and a plurality of second conductivity-type circuit devices on the substrate,
a second substrate structure including a plurality of gate electrodes, and an input/output pad electrically connected to the plurality of first conductivity-type circuit devices and the plurality of second conductivity-type circuit devices; and
a controller electrically connected to the integrated circuit device through the input/output pad and configured to control the integrated circuit device,
wherein each of the plurality of first conductivity-type circuit devices includes:
a first gate structure including a first interfacial insulating layer on the substrate; a first gate dielectric layer on the first interfacial insulating layer; a first work function tuning layer on the first gate dielectric layer; and a plurality of first gate conductive layers on the first work function tuning layer; and
a first source/drain region in the substrate on opposite sides of the first gate structure,
wherein each of the plurality of second conductivity-type circuit devices includes:
a second gate structure including a second interfacial insulating layer on the substrate; a second gate dielectric layer on the second interfacial insulating layer; a diffusion barrier on the second gate dielectric layer; a second work function tuning layer on the diffusion barrier; and a plurality of second gate conductive layers on the second work function tuning layer; and
a second source/drain region in the substrate on opposite sides of the second gate structure.
